(19) United States
(12) Patent Application Publication
(10) Pub. No.: US 2026/0140149 A1
(43) Pub. Date: May 21, 2026

(54) VOLTAGE SENSING DEVICE HAVING MICRO ELECTRO MECHANICAL SYSTEMS (MEMS) ELEMENT

(71) Applicant: INDUSTRIAL TECHNOLOGY RESEARCH INSTITUTE, Hsinchu (TW)

(72) Inventors: Yu-Wen HSU, Tainan City (TW); Jen-Chieh LI, Tainan City (TW); Chin-Jou KUO, Tainan City (TW); Chao-Ta HUANG, Hsinchu City (TW)

(73) Assignee: INDUSTRIAL TECHNOLOGY RESEARCH INSTITUTE, Hsinchu (TW)

(21) Appl. No.: 19/387,357

(22) Filed: Nov. 12, 2025

(30) Foreign Application Priority Data
Nov. 15, 2024 (TW) 113144035
Dec. 19, 2024 (CN) 202411880809.8

(51) Int. Cl. G01R 19/00; G01R 19/10

(52) U.S. Cl. CPC G01R 19/0046; G01R 19/0038; G01R 19/10

(57) ABSTRACT

A voltage sensing device having micro electro mechanical systems (MEMS) element includes a MEMS sensing element, a transimpedance amplifying circuit, a differentiation circuit and a signal detection circuit. The MEMS sensing element is configured to sense an input voltage to generate a sensed current. The transimpedance amplifying circuit is connected to an output end of the MEMS sensing element. The transimpedance amplifying circuit is configured to receive the sensed current, convert the sensed current into an amplified voltage. The differentiation circuit is connected to the transimpedance amplifying circuit. The signal detection circuit is connected to an output end of the differentiation circuit. The signal detection circuit is configured to detect the differentiated signal, determine whether the differentiated signal exhibits a sudden voltage change and identifies a time point of the sudden voltage change.

### CROSS-REFERENCE TO RELATED APPLICATIONS

This non-provisional application claims priority under 35 U.S.C. § 119(a) on Patent Application No(s). 113144035 filed in Republic of China (Taiwan) on Nov. 15, 2024, and Patent Application No(s). 202411880809.8 filed in China on Dec. 19, 2024, the entire contents of which are hereby incorporated by reference.

### BACKGROUND

### 1. Technical Field

This disclosure relates to a voltage sensing device, and more particularly to a voltage sensing device having micro electro mechanical systems (mems) element.

### 2. Related Art

In daily life and work, voltage measurement is often necessary to ensure the accuracy of components or systems. A multimeter can be used to measure the root mean square (RMS) value of both AC and DC voltages. An oscilloscope can be used to observe voltage variation and is typically employed in laboratory environments. In addition to multimeters and oscilloscopes, many voltage measurement techniques rely on resistive or capacitive voltage dividers for measurement.

### SUMMARY

According to one or more embodiment of this disclosure, a voltage sensing device having micro electro mechanical system (MEMS) element includes a MEMS sensing element, a transimpedance amplifying circuit, a differentiation circuit and a signal detection circuit. The MEMS sensing element is configured to sense an input voltage to induce a sensed current. The transimpedance amplifying circuit is connected to an output end of the MEMS sensing element to receive the sensed current and convert the sensed current into an amplified voltage. The differentiation circuit is connected to an output end of the transimpedance amplifying circuit, and is configured to receive the amplified voltage and differentiate the amplified voltage to generate a differentiated signal.

According to one or more embodiment of this disclosure, a voltage sensing device having MEMS element includes a MEMS sensing element, a transimpedance amplifying circuit, a differentiation circuit and a signal detection circuit. The MEMS sensing element includes at least one fixed part, a movable part, at least one elastic part connected to the at least one fixed part and the movable part, respectively, a sensing part, and a driving part configured to sense an input voltage. The input voltage causes the driving part and the movable part to induce a voltage difference therebetween, and the voltage difference displaces the movable part to induce a sensed current in the sensing part, and a displacement of the movable part is proportional to a square of the voltage difference. The transimpedance amplifying circuit is connected to an output end of the MEMS sensing element to receive the sensed current and convert the sensed current into an amplified voltage, wherein the amplified voltage may be derived from amplifying a first derivative of a square of the voltage difference. The differentiation circuit is connected to an output end of the transimpedance amplifying circuit, and is configured to receive the amplified voltage and differentiate the amplified voltage to generate a differentiated signal. The signal detection circuit is connected to an output end of the differentiation circuit, the signal detection circuit is configured to detect the differentiated signal, determine whether the differentiated signal exhibits a sudden voltage change and identifies a time point of the sudden voltage change in the differentiated signal occurs.

### BRIEF DESCRIPTION OF THE DRAWINGS

The disclosure will become more fully understood from the detailed description given hereinbelow and the accompanying drawings which are given by way of illustration only and thus are not limitative of the disclosure and wherein:

FIG. 1 is a schematic diagram illustrating a voltage sensing device having MEMS element according to a first embodiment of the disclosure;

FIG. 2 is a schematic diagram illustrating a voltage sensing device having MEMS element according to a second embodiment of the disclosure;

FIG. 3 is a schematic diagram illustrating a voltage sensing device having MEMS element according to a third embodiment of the disclosure;

FIG. 4 is a schematic diagram illustrating a voltage sensing device having MEMS element according to a fourth embodiment of the disclosure;

FIG. 5 is a schematic diagram illustrating a voltage sensing device having MEMS element according to a fifth embodiment of the disclosure;

FIG. 6 is a schematic diagram illustrating a voltage sensing device having MEMS element according to a sixth embodiment of the disclosure;

Part (a) of FIG. 7 is a structural diagram illustrating a MEMS sensing element according to an embodiment of the disclosure, part (a) of FIG. 7 is a diagram illustrating a situation where an electrostatic force is generated between the driving part and the movable part of the MEMS sensing element of part (a);

FIG. 8 is a schematic diagram illustrating a voltage sensing device having MEMS element according to a seventh embodiment of the disclosure;

FIG. 9 is a diagram illustrating a sensing result of the voltage sensing device having MEMS element of the disclosure sensing a high frequency signal;

FIG. 10 is a diagram illustrating a sensing result of the voltage sensing device having MEMS element of the disclosure under normal voltage condition;

FIG. 11a is a diagram illustrating a sensing result of the voltage sensing device having MEMS element of the disclosure under an abnormal voltage condition;

FIG. 11b is partially enlarged diagram of FIG. 11a;

FIG. 11c is an example of an input voltage input to the MEMS sensing element;

FIG. 11d is an example of a square of the input voltage of FIG. 11c, FIG. 11e shows a first derivative derived from differentiating the square of the input voltage of FIG. 11d;

FIG. 11f shows a second derivative derived from further differentiating the first derivative of FIG. 11e;

FIG. 11g is another example of an input voltage input to the MEMS sensing element;

FIG. 11h is another example of a square of the input voltage of FIG. 11g;

FIG. 11i shows a first derivative of the square of the input voltage of FIG. 11h;

FIG. 11j shows a second derivative of the square of the input voltage of FIG. 11i;

FIG. 12 is a schematic diagram illustrating a voltage sensing device having MEMS element according to an eighth embodiment of the disclosure;

FIG. 13 is a circuit diagram illustrating an implementation of a signal adjustment element;

FIG. 14 is a partial schematic diagram illustrating a voltage sensing device having MEMS element according to a ninth embodiment of the disclosure;

FIG. 15a is a schematic diagram illustrating the input voltage input into the MEMS sensing element comprising a sudden voltage drop and a sudden voltage recovery;

FIG. 15b is an example of a square of the input voltage of FIG. 15a;

FIG. 15c shows a first derivative of the square of the input voltage of FIG. 15b;

FIG. 15d shows a second derivative of the square of the input voltage of FIG. 15c;

FIG. 16 is a schematic diagram illustrating a voltage sensing device having MEMS element according to a tenth embodiment of the disclosure;

FIG. 17 is a structural diagram illustrating a MEMS sensing element according to another embodiment of the disclosure; and

FIG. 18 is a schematic diagram illustrating a voltage sensing device having MEMS element according to an eleventh embodiment of the disclosure.

### DETAILED DESCRIPTION

In the following detailed description, for purpose of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

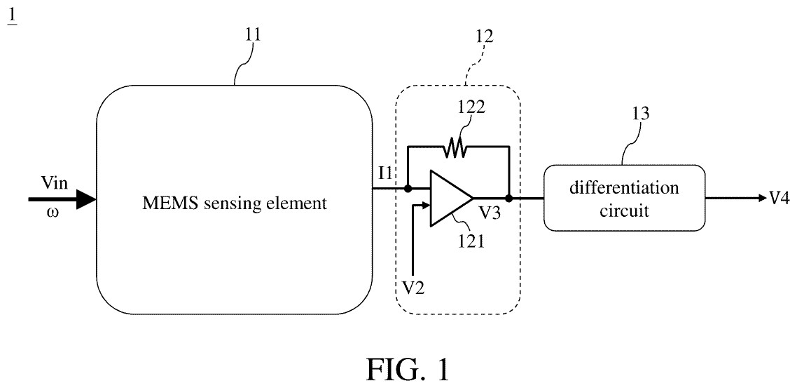

Please refer to FIG. 1, which is a schematic diagram illustrating a voltage sensing device 1 having micro-electro-mechanical system (MEMS) element according to a first embodiment of the disclosure. As shown in FIG. 1, the voltage sensing device 1 having micro-electro-mechanical system (MEMS) element includes a MEMS sensing element 11, a transimpedance amplifying circuit 12 and a differentiation circuit 13. The transimpedance amplifying circuit 12 is electrically connected to an output end of the MEMS sensing element 11, and the differentiation circuit 13 is connected to an output end of the transimpedance amplifying circuit 12.

The MEMS sensing element 11 is configured to sense an input voltage Vin and generate a corresponding sensed current I1. The input voltage Vin may be either an alternating voltage (AC) or a direct voltage (DC), and the source of the input voltage Vin may include common AC power source (for example: power outlet) or DC power source (for example: battery), suitable for residential, commercial, or industrial applications, but the disclosure does not limit the source of the input voltage Vin. In an embodiment, the frequency of the sensed current I1 may be twice the frequency of the input voltage Vin. In details, the input voltage Vin is an alternating voltage (AC) and is configured to cause a frequency of the sensing current to be twice a frequency of an alternating voltage. For example, if the frequency of the input voltage is w, then the resulting frequency of the sensed current I1 is 2ω.

The transimpedance amplifying circuit 12 is configured to receive the sensed current I1, and convert the sensed current I1 into an amplified voltage V3. This conversion process may include converting the sensed current into a sensed voltage, followed by amplifying the sensed voltage into the amplified voltage V3. The amplified voltage V3 may be derived from amplifying a first derivative of a square of a voltage difference between a driving part and a movable part of the MEMS sensing element 11. In one embodiment, the square of the voltage difference is the square of the input voltage Vin, expressed as (Vin²). In another embodiment, the square of the voltage difference is the square of sum of the input voltage Vin and a body voltage Vbody, expressed as (Vin+Vbody)². The differentiation circuit 13 is configured to receive the amplified voltage V3 and differentiate the amplified voltage V3 to generate a differentiated signal V4, wherein the differentiated signal V4 may serve as an indicator of whether the input voltage Vin exhibits a sudden voltage change (e.g., sudden voltage drop or sudden voltage rise). The differentiated signal V4 is substantially a voltage derived from differentiating the amplified voltage V3. In other words, the differentiated signal V4 is substantially a voltage which may be derived from a second derivative of the square of the input voltage Vin, and then amplifying the second derivative of the square of the input voltage Vin, or substantially a voltage derived from a second derivative of the square of the sum of the input voltage Vin and the body voltage Vbody, and then amplifying the second derivative of the square of the sum of the input voltage Vin and the body voltage Vbody. The differentiated signal V4 is used to indicate whether the input voltage Vin exhibits a sudden voltage change and identify the time point of the sudden voltage change of the input voltage Vin. Specifically, a sudden voltage change in the input voltage Vin is detected when the change of the differentiated signal V4 within a specific time interval exceeds a predetermined value. Examples of events that may cause such sudden voltage change include power outages or conductor disconnections. In an embodiment, the MEMS sensing element 11 may be a wideband MEMS sensing element. For example, the resonance frequency of the MEMS sensing element 11 may be adjusted by varying a stiffness of the MEMS sensing element 11 and/or a mass of the MEMS sensing element 11, thereby easily expanding the voltage sensing range of the voltage sensing device 1 having MEMS element. The resonance frequency refers to the resonance frequency at which the MEMS sensing element 11 vibrates mechanically. In other words, by adjusting the stiffness and/or the mass of the MEMS sensing element 11, the MEMS sensing element 11 may measure input voltages Vin over a broad frequency spectrum. For example, the wideband MEMS sensing element may be capable of sensing input voltages Vin with frequencies ranging from above 1 kHz to below 80 kHz, however, the disclosure is not limited to this frequency range.

In addition, the transimpedance amplifying circuit 12 may include an amplifier 121 and a resistor 122 connected in parallel across input end and output end of the amplifier 121. Two input ends of the amplifier 121 may be configured to receive the sensed current I1 and a ground voltage V2, respectively, while the output end of the amplifier 121 may be configured to output the amplified voltage V3. The configuration of the transimpedance amplifying circuit 12 illustrated in FIG. 1 is in an example, and the disclosure is not limited thereto.

With the inclusion of the differentiation circuit 13, it is possible to determine whether the input voltage Vin exhibits the sudden voltage change within a short time interval, and to accurately identify the exact time point at which such a sudden voltage change occurs. Further, when the output of the differentiation circuit 13 exhibits a sudden voltage change that exceeds a predetermined value within a specific time interval, it corresponds to a sudden voltage change in the input voltage Vin. The midpoint of the specific time interval may be defined as the time point at which the sudden voltage change occurs. For instance, in the event of a blackout in a power system, the differentiation circuit 13 may detect the corresponding sudden voltage change in the input voltage Vin within 1 millisecond. However, the disclosure is not limited to this specific time interval.

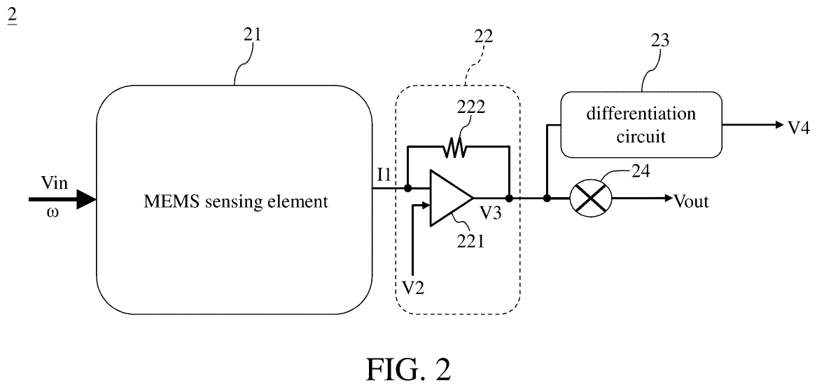

Please refer to FIG. 2, which is a schematic diagram illustrating a voltage sensing device having MEMS element according to a second embodiment of the disclosure. As shown in FIG. 2, the voltage sensing device 2 having MEMS element includes a MEMS sensing element 21, a transimpedance amplifying circuit 22, a differentiation circuit 23, and a demodulator 24. The transimpedance amplifying circuit 22 is connected to the output end of the MEMS sensing element 21, while the differentiation circuit 23 and the demodulator 24 are both connected to the output end of the transimpedance amplifying circuit 22. The MEMS sensing element 21, the transimpedance amplifying circuit 22, and the differentiation circuit 23 may be implemented in the same manner as the MEMS sensing element 11, the transimpedance amplifying circuit 12, and the differentiation circuit 13 described in the first embodiment (FIG. 1), and therefore, detailed descriptions thereof are omitted for brevity.

The demodulator 24 may receive the amplified voltage V3 and modulate the amplified voltage V3 by removing a mixed signal of the amplified voltage V3, thereby outputting a modulated voltage Vout. In an embodiment, the modulated voltage Vout may be a direct current voltage. For example, the demodulator 24 may filter out portions of the carrier wave embedded in the amplified voltage V3, and retain the low-frequency or mid-frequency modulated components to generate the modulated voltage Vout. As a result, the demodulator 24 effectively reduces irrelevant high-frequency noise, thereby improving the signal-to-noise ratio (SNR).

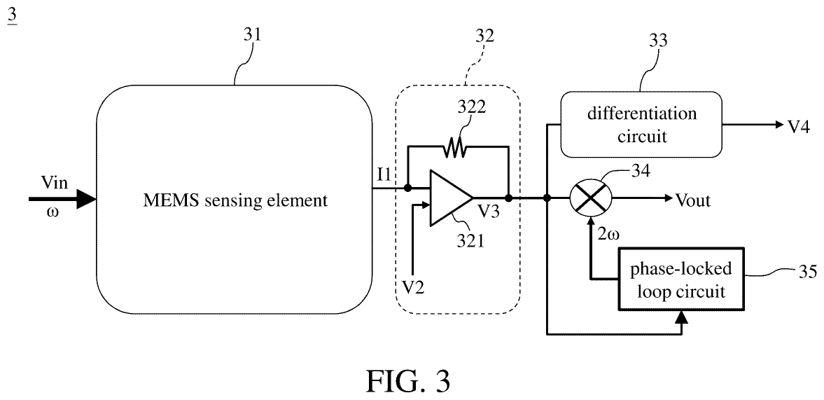

Please refer to FIG. 3, which is a schematic diagram illustrating a voltage sensing device having MEMS element according to a third embodiment of the disclosure. As shown in FIG. 3, the voltage sensing device 3 having MEMS element includes a MEMS sensing element 31, a transimpedance amplifying circuit 32, a differentiation circuit 33, a demodulator 34, and a phase-locked loop (PLL) circuit 35. The transimpedance amplifying circuit 32 is connected to the output end of the MEMS sensing element 31. Both the differentiation circuit 33 and the demodulator 34 are connected to the output end of the transimpedance amplifying circuit 32. An input end of the phase-locked loop circuit 35 is connected to the output end of the transimpedance amplifying circuit 32, and an output end of the phase-locked loop circuit 35 is connected to an input end of the demodulator 34. The MEMS sensing element 31, the transimpedance amplifying circuit 32, the differentiation circuit 33, and the demodulator 34 may be implemented in the same manner as the MEMS sensing element 21, the transimpedance amplifying circuit 22, the differentiation circuit 23 and the demodulator 24 described in the second embodiment shown in FIG. 2. Accordingly, detailed descriptions of these components are omitted for brevity.

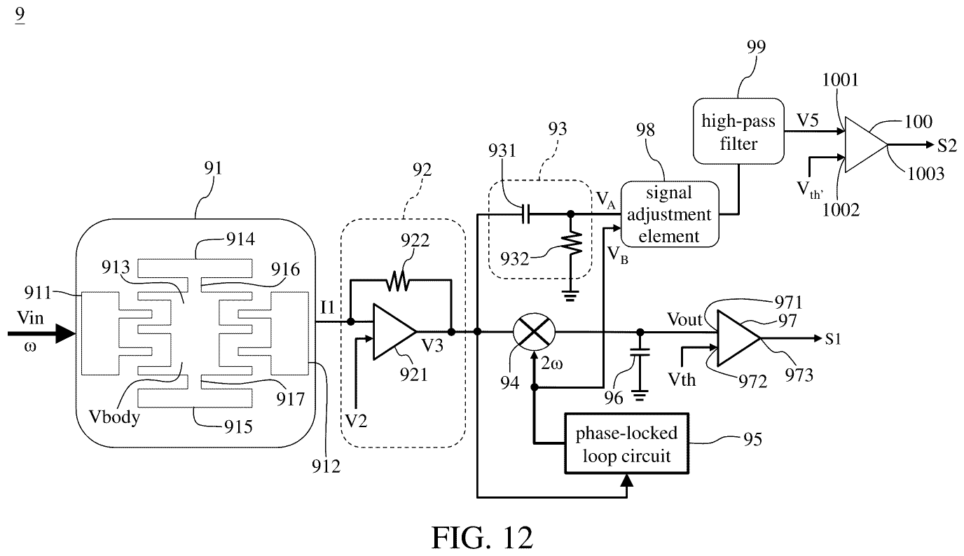

The phase-locked loop circuit 35 receives the amplified voltage V3 from the transimpedance amplifying circuit 32, locks onto a frequency of the amplified voltage V3 and outputs a signal with stable frequency (2Ω) (for example, second voltage V_{B} of FIG. 12) to the demodulator 34. The demodulator 34 performs demodulation on the signal from the phase-locked loop circuit 35 to remove mixed signal, thereby obtaining the modulated voltage Vout.

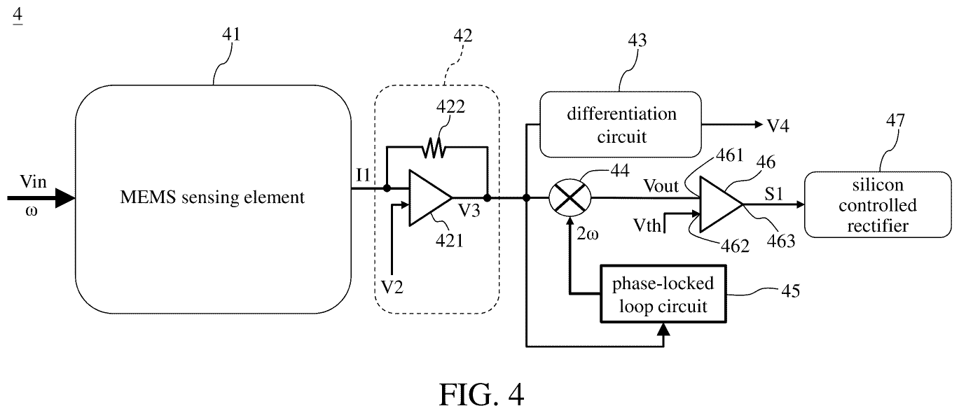

Please refer to FIG. 4, which is a schematic diagram illustrating a voltage sensing device having MEMS element according to a fourth embodiment of the disclosure. As shown in FIG. 4, the voltage sensing device 4 having MEMS element includes a MEMS sensing element 41, a transimpedance amplifying circuit 42, a differentiation circuit 43, a demodulator 44, a phase-locked loop circuit 45, a first comparator 46 and a silicon controlled rectifier (SCR) 47. The transimpedance amplifying circuit 42 is connected to the output end of the MEMS sensing element 41. Both the differentiation circuit 43 and the demodulator 44 are connected to the output end of the transimpedance amplifying circuit 42. The input end of the phase-locked loop circuit 45 is also connected to the output end of the transimpedance amplifying circuit 42, and the output end of the phase-locked loop circuit 45 is connected to the input end of the demodulator 44. The first comparator 46 includes a first input end 461, a second input end 462, and an output end 463. The first input end 461 of the first comparator 46 is connected to the output end of the demodulator 44, and the output end 463 of the first comparator 46 is connected to the input end of the silicon controlled rectifier 47.

The MEMS sensing element 41, the transimpedance amplifying circuit 42, differentiation circuit 43, the demodulator 44, and the phase-locked loop circuit 45 of the voltage sensing device 4 having MEMS element may be implemented in the same manner as the MEMS sensing element 31, the transimpedance amplifying circuit 32, the differentiation circuit 33, the demodulator 34, and the phase-locked loop circuit 35 of the third embodiment shown in FIG. 3. Therefore, detailed descriptions of these components are omitted for brevity.

The first input end 461 of the first comparator 46 is configured to receive the modulated voltage Vout. The second input end 462 of the first comparator 46 is configured to receive a first threshold voltage Vth. The first comparator 46 may be configured to determine whether the voltage value of the modulated voltage Vout exceeds a predetermined threshold (for example, first threshold voltage). The output end 463 of the first comparator 46 is configured to output a first comparison result S1, which indicates the result of comparing the modulated voltage Vout with the first threshold voltage Vth. The first comparison result S1 may be used to drive the silicon controlled rectifier 47 when the first comparison result S1 indicates that the modulated voltage Vout exceeds the first threshold voltage Vth. In some embodiments, the first threshold voltage Vth may be adjusted based on application-specific requirements or voltage criteria. For example, the first threshold voltage Vth may be set as 75% of the maximum value of the modulated voltage Vout. The standard for identifying whether the input voltage Vin exhibits a sudden voltage change may include two conditions: (1) the modulated voltage Vout exceeds the first threshold voltage Vth at a time point (tₙ); and (2) the voltage drop of the modulated voltage Vout during a time interval (tₙ, tₙ₋₁) exceeds a default magnitude—for example, a 5% drop in amplitude of the modulated voltage Vout during a time interval (tn, tn−1).

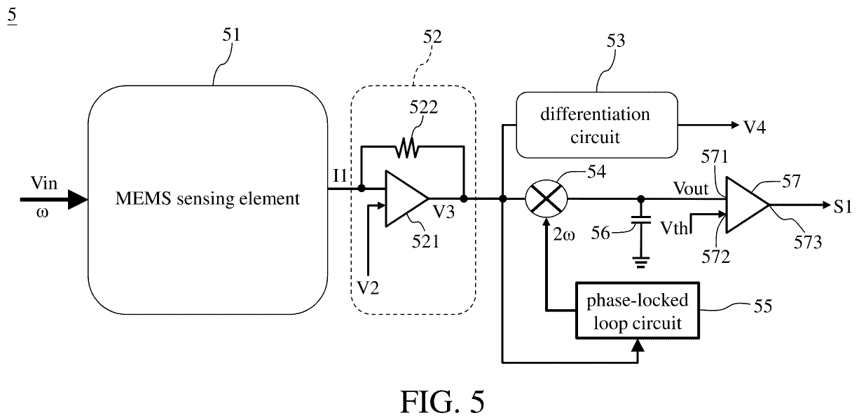

Please refer to FIG. 5, which is a schematic diagram illustrating a voltage sensing device having MEMS element according to a fifth embodiment of the disclosure. As shown in FIG. 5, the voltage sensing device 5 having MEMS element includes a MEMS sensing element 51, a transimpedance amplifying circuit 52, a differentiation circuit 53, a demodulator 54, a phase-locked loop circuit 55, a low-pass filter 56 and a first comparator 57. The transimpedance amplifying circuit 52 is connected to an output end of the MEMS sensing element 51. The differentiation circuit 53 and the demodulator 54 are connected to an output end of the transimpedance amplifying circuit 52, respectively. An input end of the phase-locked loop circuit 55 is connected to the output end of the transimpedance amplifying circuit 52, and an output end of the phase-locked loop circuit 55 is connected to an input end of the demodulator 54. The first comparator 57 includes a first input end 571, a second input end 572 and an output end 573. An input end of the low-pass filter 56 is connected to an output end of the demodulator 54, while an output end of the low-pass filter 56 is connected to the first input end 571 of the first comparator 57.

The MEMS sensing element 51, the transimpedance amplifying circuit 52, differentiation circuit 53, the demodulator 54, the phase-locked loop circuit 55, and the first comparator 57 of the voltage sensing device 5 having MEMS element may be implemented in the same manner as the MEMS sensing element 41, the transimpedance amplifying circuit 42, the differentiation circuit 43, the demodulator 44, the phase-locked loop circuit 45, and the first comparator 46 of the fourth embodiment shown in FIG. 4. Accordingly, detailed descriptions of these components are omitted for brevity.

The low-pass filter 56 may be configured to filter out high frequency components from the voltage output by the demodulator 54. In some embodiments, the low-pass filter 56 may be implemented using a capacitor. One end of the capacitor is connected to both the output end of the demodulator 54 and the first input end 571 of the first comparator 57, while the another end of the capacitor is grounded. Furthermore, when the frequency of the sensed current I1 output from the MEMS sensing element 51 is 2ω, and the output voltage of the demodulator 54 contains a frequency component of 4ω, the low-pass filter 56 may effectively filter out the frequency component of 4ω, thereby eliminating unnecessary high-frequency noise.

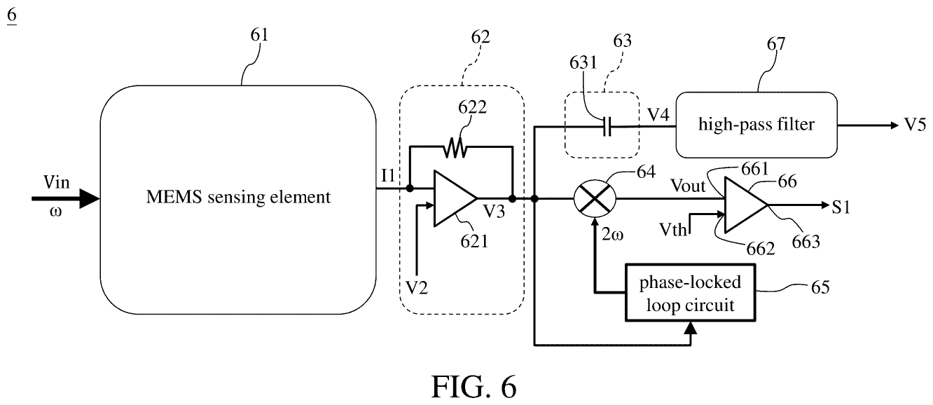

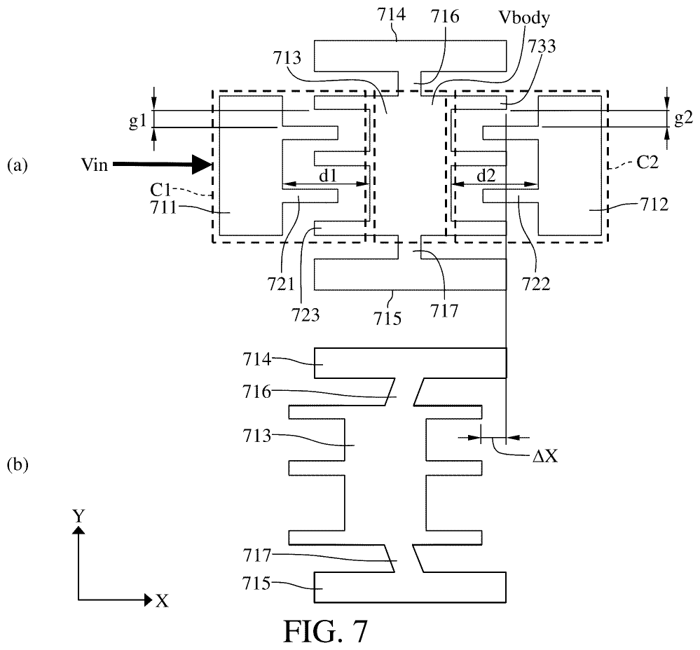

Please refer to FIG. 6, which is a schematic diagram illustrating a voltage sensing device having MEMS element according to a sixth embodiment of the disclosure. As shown in FIG. 6, the voltage sensing device 6 having MEMS element includes a MEMS sensing element 61, a transimpedance amplifying circuit 62, a differentiation circuit 63, a demodulator 64, a phase-locked loop circuit 65, a first comparator 66 and a high-pass filter 67. The transimpedance amplifying circuit 62 is connected to an output end of the MEMS sensing element 61. The differentiation circuit 63 and the demodulator 64 are connected to an output end of the transimpedance amplifying circuit 62, respectively. An input end of the phase-locked loop circuit 65 is connected to the output end of the transimpedance amplifying circuit 62, and an output end of the phase-locked loop circuit 65 is connected to an input end of the demodulator 64. The first comparator 66 includes a first input end 661, a second input end 662 and an output end 663.

The MEMS sensing element 61, transimpedance amplifying circuit 62, the demodulator 64, the phase-locked loop circuit 65, and the first comparator 66 of the voltage sensing device 6 having MEMS element may be implemented in the same manner as the MEMS sensing element 41, the transimpedance amplifying circuit 42, the demodulator 44, the phase-locked loop circuit 45, and the first comparator 46 of the fourth embodiment shown in FIG. 4. Accordingly, detailed descriptions of these components are omitted for brevity.

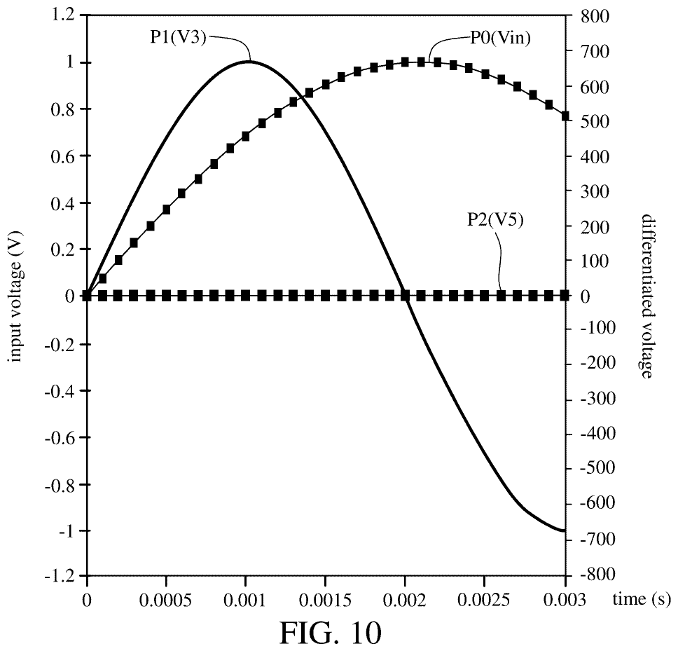

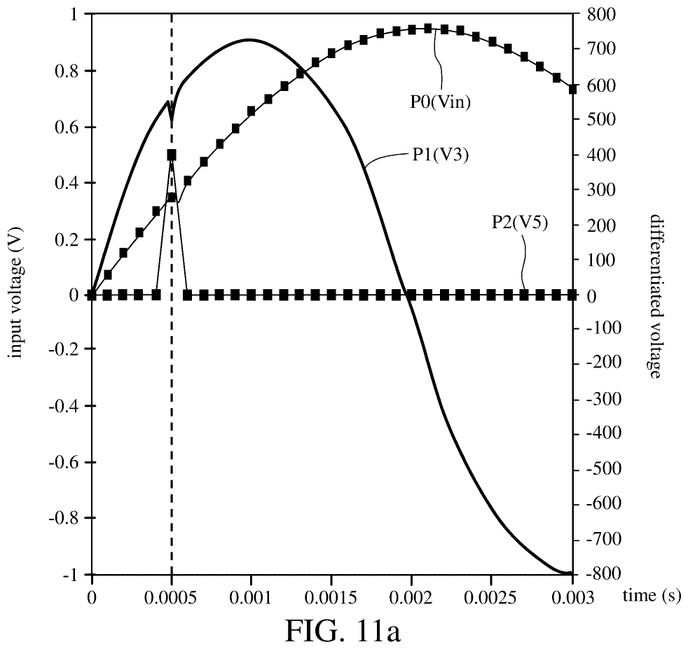

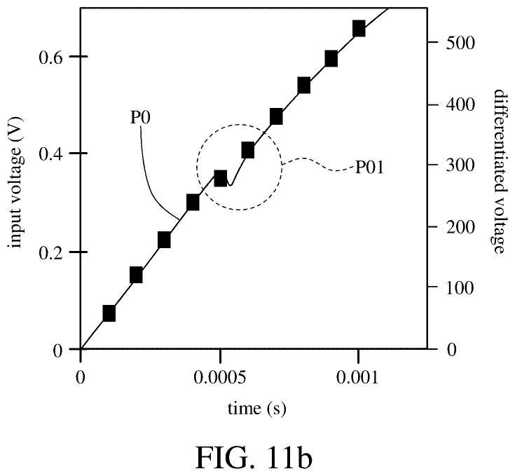

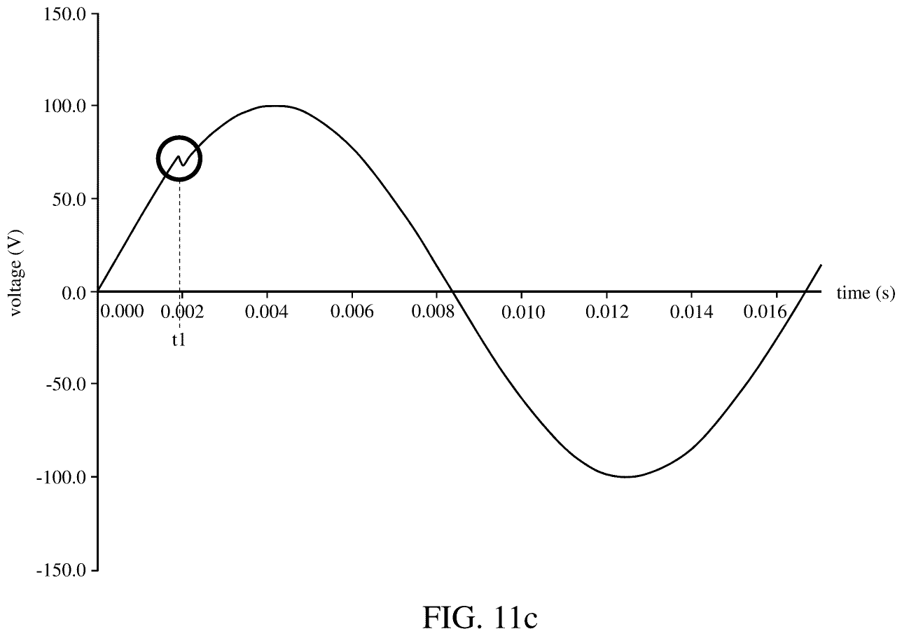

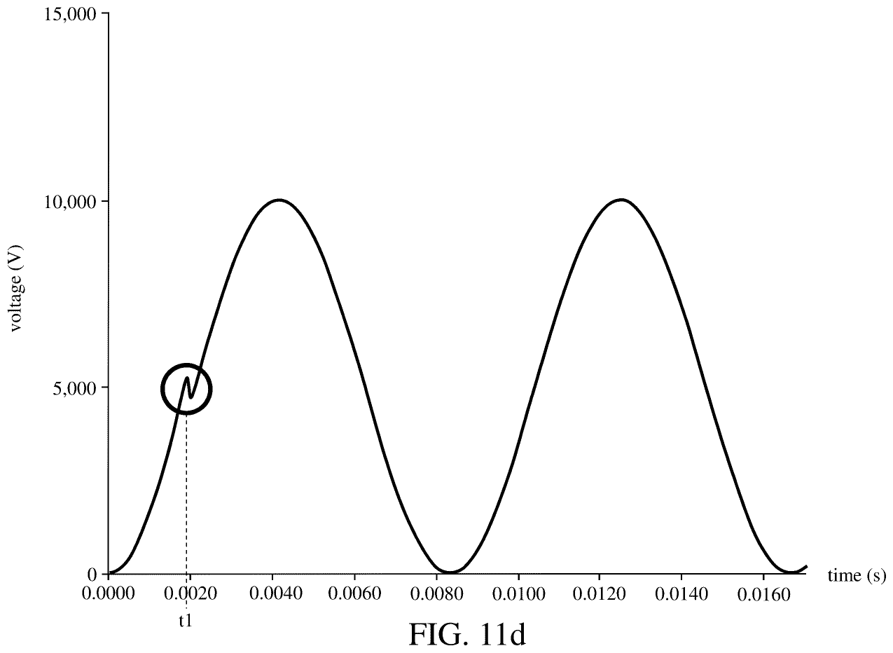

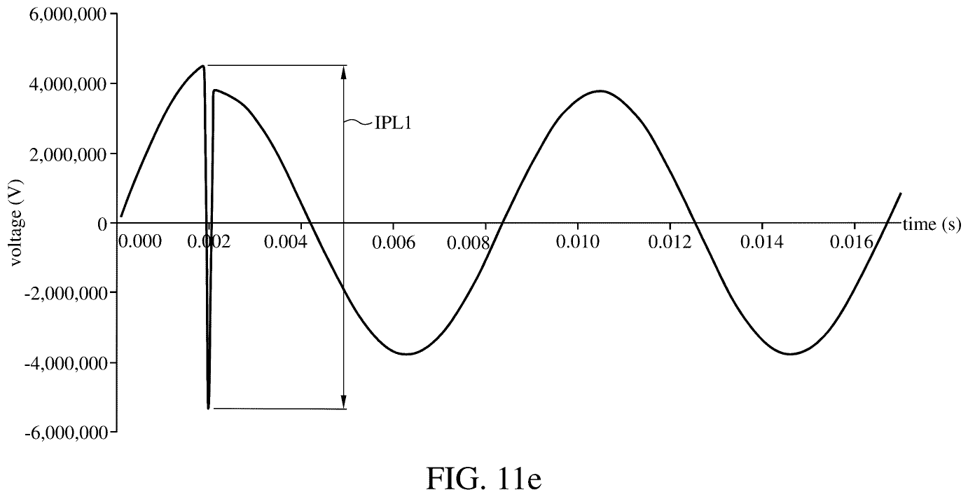

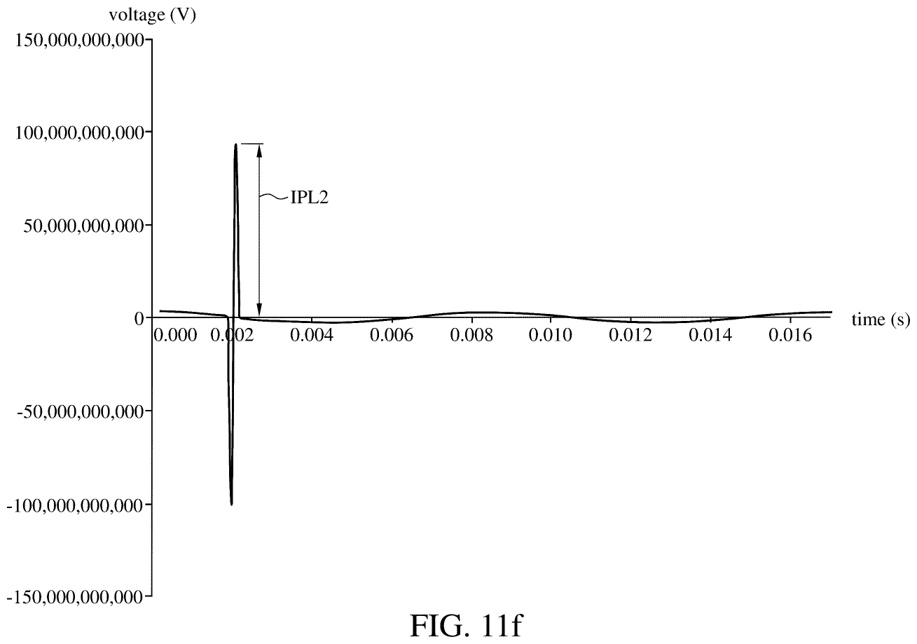

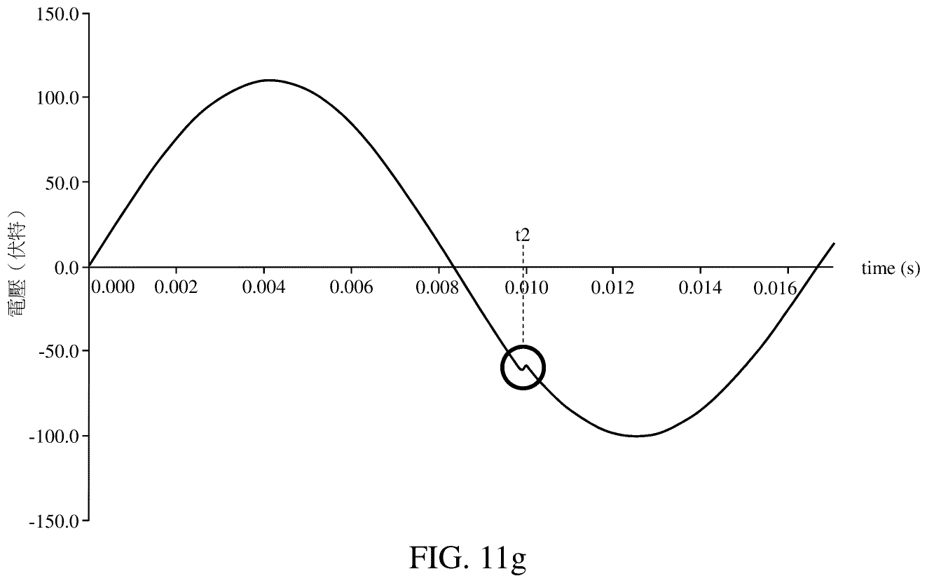

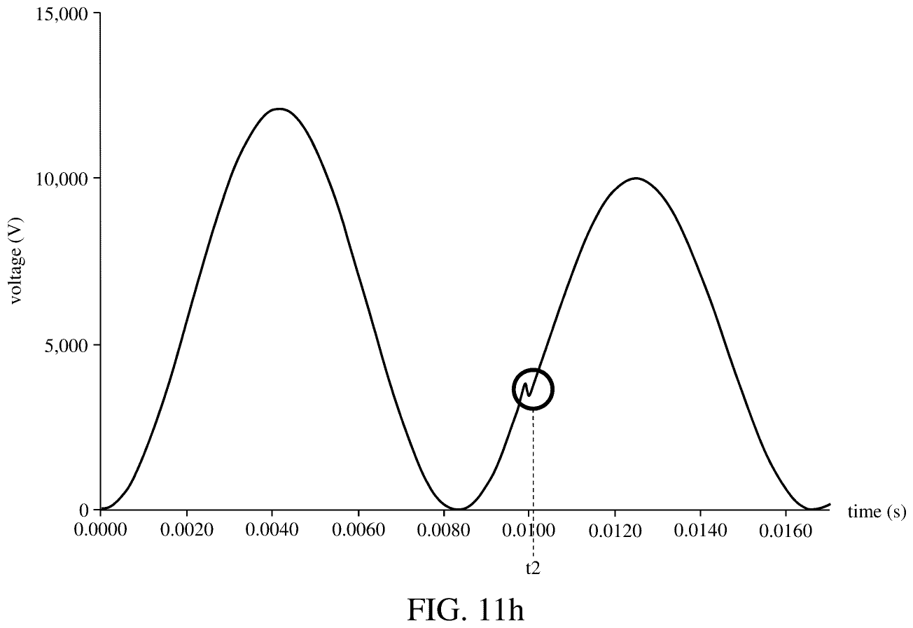

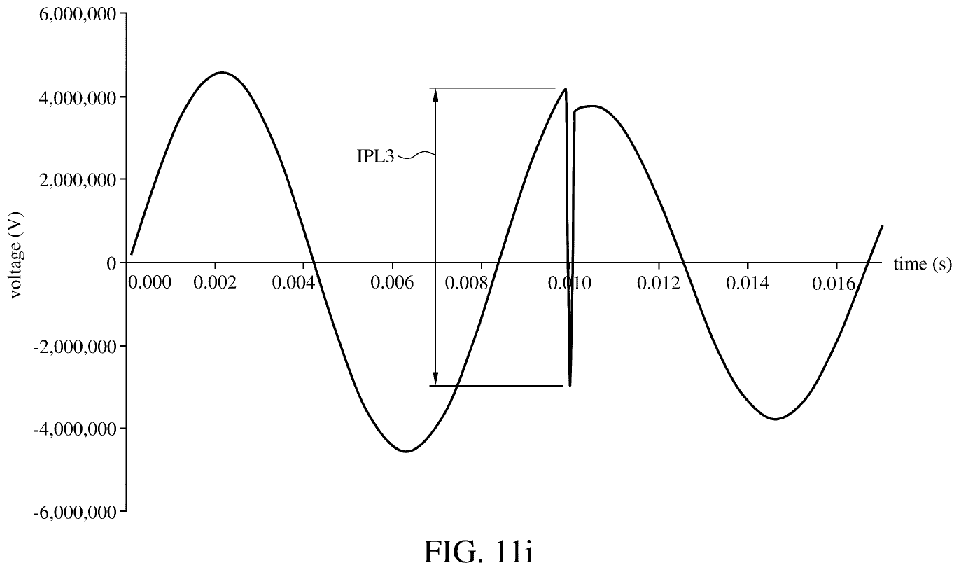

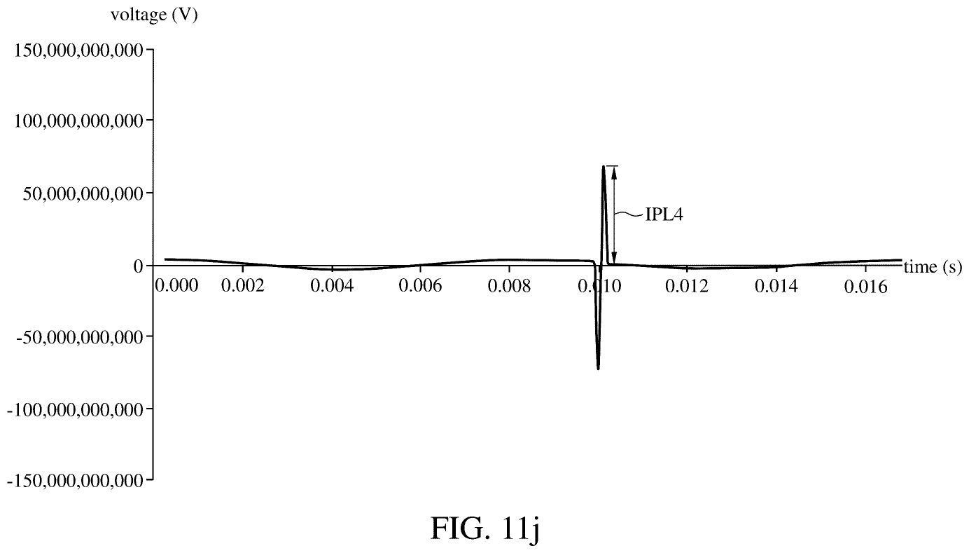

In some embodiments, the differentiation circuit 63 may include a differential capacitor 631. One end of the differential capacitor 631 is connected to the output end of the transimpedance amplifying circuit 62, while another end of the differential capacitor 631 is connected to an input end of the high-pass filter 67. The amplified voltage V3 output by the transimpedance amplifying circuit 62 may be derived from the first derivative of the square of the input voltage (Vin²). The differentiated signal V4, output by the differentiation circuit 63, may then be derived from the second derivative of the square of input voltage (Vin²). The differentiated signal V4 may be used to determine whether the input voltage Vin exhibits a sudden voltage change. Within a specific time interval, the corresponding amplified voltage V3 may be represented as a voltage curve (e.g., curve P1 shown in FIG. 10 or FIG. 11a). After filtering the differentiated signal V4 through the high-pass filter 67, the resulting filtered voltage V5 may be represented as another voltage curve (e.g., curve P2 shown in FIG. 11a). When the input voltage Vin exhibits a sudden voltage change at a time point, the curve of the amplified voltage V3 exhibits a sudden voltage change (sudden voltage drop or sudden voltage rise) at the same time point. For example, as shown in FIG. 11a, curve P1 of the amplified voltage V3 shows a sudden voltage drop at 0.0005 second. Furthermore, when the input voltage Vin exhibits a sudden voltage drop at a time point, the filtered voltage V5 exhibits a pulse which lies entirely within the positive range at the same time point—illustrated, for instance, by curve P2 in FIG. 11a. Therefore, by detecting a sudden voltage change (sudden voltage drop or sudden voltage rise) in the amplified voltage V3 within an extremely short time interval, or by detecting the pulse of the filtered voltage V5 which lies entirely within the positive range within that an extremely short time interval, it may be determined whether the input voltage Vin exhibits a sudden voltage change.

Additionally, the high-pass filter 67 shown in FIG. 6 is configured to detect whether the differentiated signal V4 exhibits a sudden voltage change—either a sudden voltage drop or sudden voltage rise—within an extremely short time interval. The high-pass filter 67 may filter the differentiated signal V4 to generate the filtered voltage V5, thereby filtering out unnecessary low-frequency components from the differentiated signal V4, such as low frequency signals at frequency ω. Specifically, under normal conditions, the input voltage Vin exhibits a sinusoidal waveform, and the differentiated signal V4—which may be derived from the second derivative of the square of the input voltage (Vin²)—exhibits a cosine waveform. Here, “normal” means that neither the input voltage Vin nor the differentiated signal V4 output by the differentiation circuit 63 exhibits any sudden voltage change. The normal differentiated signal V4 changes gradually over a specified time interval and is thus filtered when passing through the high-pass filter 67. In another case, when the filtered voltage V5 is not equal to zero at a specific time point, it indicates that the differentiated signal V4 exhibits an abnormal sudden rise or sudden drop at the specific time point. The filtered voltage V5 which is not equal to zero implies that the input voltage Vin exhibits a sudden voltage change (sudden voltage drop or sudden voltage rise) within an extremely short time interval. Therefore, by simply comparing the filtered voltage V5 with a predetermined threshold (for example, second threshold voltage), it becomes possible to identify sudden voltage change in the input voltage Vin within a very short time interval. This method obviates the need for a dedicated microprocessor unit (MPU) to perform complex numerical calculations, such as digitizing the differentiated signal V4. Furthermore, it allows precise identification of the exact time point at which the sudden voltage change occurs.

Please refer to FIG. 7, where part (a) illustrates a structural diagram of a MEMS sensing element according to an embodiment of the disclosure, and part (b) depicts the movable part 713 under electrostatic force between the driving part and the movable part of the MEMS sensing element shown in part (a). The MEMS sensing element structure in FIG. 7 may be applied to any of the MEMS sensing elements illustrated in FIG. 1 through FIG. 6. As shown in part (a), the MEMS sensing element 71 includes a driving part 711, a sensing part 712, a movable part 713, two fixed parts 714 and 715, and two elastic parts 716 and 717. The movable part 713 is disposed between the driving part 711 and the sensing part 712. One side of the movable part 713 and the driving part 711 together form a first capacitor C1, while another side of the movable part 713 and the sensing part 712 form a second capacitor C2. The driving part 711 includes at least one fixed input electrode 721, and the sensing part 712 includes at least one fixed output electrode 722. The movable part 713 has a movable electrode 723 on one side and a movable electrode 733 on the opposite side. The movable electrode 723 on one side of the movable part 713 and the fixed input electrode 721 of the driving part 711 are arranged in an interdigitated configuration to form the first interdigitated electrode, thus forming the first capacitor C1 between the movable part 713 and the driving part 711. Similarly, the movable electrode 733 on the opposite side of the movable part 713 and the fixed output electrode 722 of the sensing part 712 are arranged in an interdigitated configuration to form the second interdigitated electrode, thereby forming the second capacitor C2 between the movable part 713 and the sensing part 712. For clarity, part (b) of FIG. 7 illustrates the movable part 713, the two fixed parts 714 and 715, and the two elastic parts 716 and 717 to facilitate description. However, part (b) is not intended to limit the MEMS sensing element 71 to only include these components.

The elastic parts 716 and 717 are disposed on two sides of the movable part 713 respectively. The elastic part 716 connects the fixed part 714 to the movable part 713, and the elastic part 717 connects the fixed part 715 to the movable part 713. The stiffness of the elastic parts 716, 717 and the mass of the movable part 713 each is related to the sensing bandwidth of the MEMS sensing element 71. The sensing bandwidth of the MEMS sensing element 71 may be expanded by adjusting the stiffness of the elastic parts 716 and 717 and/or the mass of the movable part 713. The sensing bandwidth of the MEMS sensing element 71 is proportional to the square root of the stiffness of the elastic parts 716 and 717, and inversely proportional to the square root of the mass of the movable part 713. Therefore, by adjusting the stiffness of the elastic parts 716 and 717 and/or the mass of the movable part 713, the detectable voltage frequency range of the voltage sensing device having MEMS element may be conveniently adjusted.

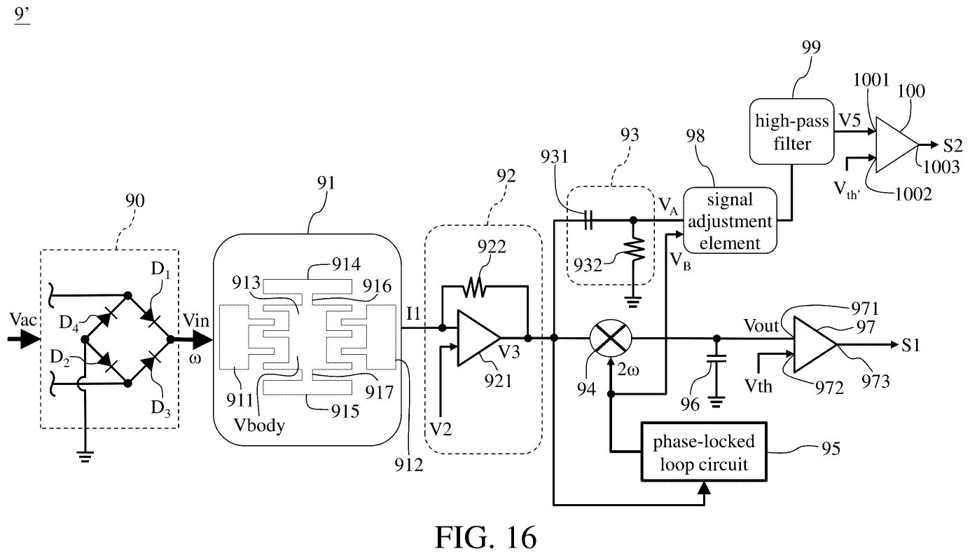

The driving part 711 may be configured to receive an AC input voltage Vin, and the input voltage Vin may be represented as sin(t) or V·sin(t). In other words, the input voltage Vin is an AC voltage, wherein the input of the AC voltage of the MEMS sensing element 71 may be applied to the MEMS sensing element 71 to make the vibration frequency of the movable part 713 become twice the frequency of the AC voltage. Upon applying the input voltage Vin to the driving part 711, a voltage difference ΔV is induced between the fixed input electrode 721 of the driving part 711 and the movable electrode 723 of the movable part 713. This voltage difference ΔV induces an electrostatic force between the driving part 711 and the movable part 713. The electrostatic force moves the movable part 713 by a displacement ΔX as shown in part (b) of FIG. 7, and the displacement ΔX causes the movable part 713 to move toward the driving part 711 and away from the sensing part 712. Consequently, the first distance d1 between one side the movable part 713 and an inner side of the driving part 711 decreases when the movable part 713 moves toward the driving part 711. The second distance d2 between another side of the movable part 713 and an inner side of the sensing part 712 increases when the movable part 713 moves away from the sensing part 712. The increase in the second distance d2 alters the capacitance of the second capacitor C2 (formed by the movable part 713 and sensing part 712), inducing the sensing part 712 to output the sensed current I1. In one embodiment, the body voltage Vbody of the movable part 713 is set to zero to cause the voltage difference to be the input voltage Vin. Therefore, if the frequency of the input voltage Vin is ω, the sensed current I1 and the amplified voltage V3 have a frequency of 2ω. In another embodiment, the body voltage Vbody of the movable part 713 is not zero; for example, as shown in FIG. 16, the body voltage Vbody of the movable part 913 is less than zero.

The voltage difference between the movable part 713 and the driving part 711 may be expressed as sin(t). The displacement ΔX of the movable part 713 may be proportional to the square of the voltage difference (i.e., sin²(t)). This displacement ΔX causes the sensing part 712 to generate electric charges. The quantity of the electric charges on the sensing part 712 is proportional to the square of the voltage difference (sin²(t)), and the quantity of the electric charges of the movable part 713 is proportional to the square of the voltage difference (sin²(t)). In this embodiment, when an AC voltage is applied to the MEMS sensing element 71 and the body voltage Vbody of the movable part 713 is set to zero, the frequency of the sensed current I1 becomes twice that of the input AC voltage, and the amplitude of the sensed current remains positive throughout the cycle. As a result, at the time point at which the input voltage Vin exhibits a sudden voltage drop, the second derivative of the square of the input voltage (Vin²) generates a pulse that lies entirely within the positive range. This characteristic significantly simplifies the design of the signal detection circuit and reduces both the design complexity and manufacturing cost of the voltage sensing device 6 having the MEMS element. In another embodiment, the voltage sensing device having a MEMS element, which includes the MEMS sensing element 71, may further include a full wave rectifier (e.g., the full wave rectifier 90 shown in FIG. 16). In this configuration, the AC voltage is input to the full wave rectifier to generate the input voltage. The body voltage of the movable part 713 is set to a value less than zero, which significantly increases the voltage difference ΔV between the fixed input electrode 721 of the driving part 711 and the movable electrode 723 of the movable part 713, thereby increasing voltage difference to improves the sensing sensitivity of the voltage sensing device having MEMS element.

As shown in the embodiment of FIG. 6, the voltage sensing device 6 having MEMS element may determine whether the input voltage Vin exhibits the sudden voltage change by processing the sensed current I1. In addition, the current which flows through the to-be-sensed object does not pass directly through the MEMS sensing element shown in FIG. 7. Therefore, the voltage sensing device 6 having MEMS element does not cause additional electric power consumption when the to-be-sensed object is sensed. Further, as shown in FIG. 7, a large dimension of the first gap g1 between the movable electrode 723 on one side of the movable part 713 and the fixed input electrode 721 of the driving part 711 and a large dimension of the second gap g2 between the movable electrode 733 on another side of the movable part 713 and the fixed output electrode 722 of the sensing part 712 may enable the voltage sensing device having MEMS element to measure high voltages (for example, voltages exceeding 350V) on the sensed object. When applying the voltage sensing device having the MEMS element to high-voltage measurements, large dimensions of the first gap g1 and the second gap g2 in the MEMS sensing element 71 are employed to prevent structural damage caused by strong electrostatic forces. Moreover, the maximum input voltage of the MEMS sensing element 71 is proportional to the dimension of the input gap (first gap) g1 and the dimension of the output gap (second gap) g2. For instance, if the driving part 711 and the sensing part 712 maintains a constant distance therebetween (i.e., the displacement ΔX of the movable part 713 has an upper limit), then the dimension of the first gap g1 and the dimension of the second gap g2 are proportional to the square of the maximum input voltage (Max Vin²) of the MEMS sensing element 71. Therefore, if the sensing range of the input voltage needs to be adjusted or expanded, only the dimension of the first gap g1 or the dimension of the second gap g2 needs to be modified, without requiring complex redesign of the voltage sensing device 6 having the MEMS element. This approach may shorten the development process for the voltage sensing device 6 having MEMS element.

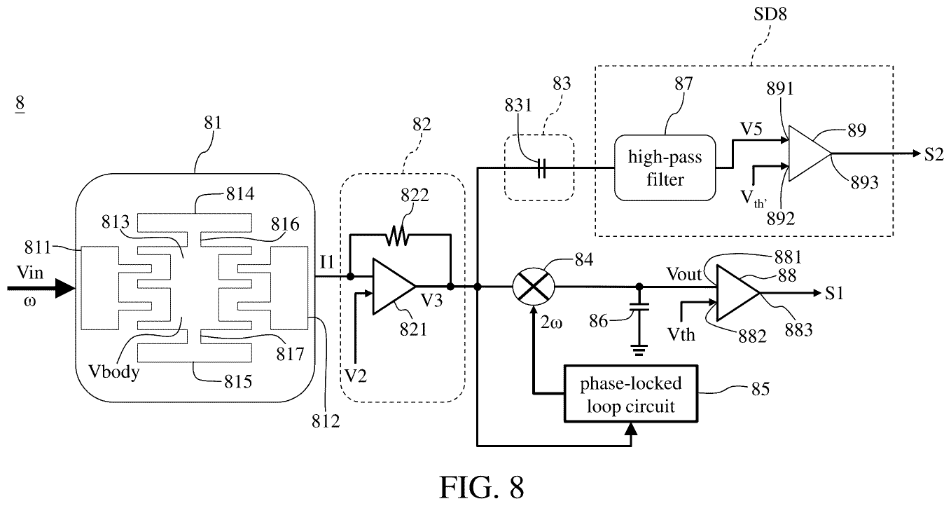

Please refer to FIG. 8, which is a schematic diagram illustrating a voltage sensing device having MEMS element according to a seventh embodiment of the disclosure. As shown in FIG. 8, the voltage sensing device 8 having MEMS element includes a MEMS sensing element 81, a transimpedance amplifying circuit 82, a differentiation circuit 83, a demodulator 84, a phase-locked loop circuit 85, a low-pass filter 86, a first comparator 88 and a signal detection circuit SD8. The transimpedance amplifying circuit 82 is connected to an output end of the MEMS sensing element 81. The differentiation circuit 83 and the demodulator 84 are connected to an output end of the transimpedance amplifying circuit 82, respectively. Further, the differentiation circuit 83 may include a differential capacitor 831, one end of the differential capacitor 831 is connected to the output end of the transimpedance amplifying circuit 82, and another end of the differential capacitor 831 is connected to an input end of the signal detection circuit SD8. An input end of the phase-locked loop circuit 85 is connected to the output end of the transimpedance amplifying circuit 82, and an output end of the phase-locked loop circuit 85 is connected to an input end of the demodulator 84.

The first comparator 88 includes a first input end 881, a second input end 882, and an output end 883. The input end of the low-pass filter 86 is connected to the output end of the demodulator 84, while the output end of the low-pass filter 86 is connected to the first input end 881 of the first comparator 88. The output end 883 of the first comparator 88 may be connected to the input end of a silicon controlled rectifier. In the embodiment illustrated in FIG. 8, the signal detection circuit SD8 includes a high-pass filter 87 and a second comparator 89. The second comparator 89 comprises a first input end 891, a second input end 892, and an output end 893. The input end of the high-pass filter 87 is connected to the output end of the differential capacitor 831, and the output end of the high-pass filter 87 is connected to the first input end 891 of the second comparator 89. In an embodiment, the signal detection circuit SD8 determines the differentiated signal V4 exhibiting the sudden voltage change when a voltage value of the modulated voltage Vout at the time point exceeds the first threshold voltage Vth and a voltage drop of the modulated voltage Vout within a time interval comprising the time point exceeds a default magnitude. In an embodiment, the signal detection circuit SD8 may determine the differentiated signal V4 exhibiting the sudden voltage change when the change of the differentiated voltage V4 exceeds a predetermined value within the time interval, wherein a middle point of the time interval is the time point of the sudden voltage change in the differentiated signal V4. Accordingly, the detection of sudden voltage change in the input voltage Vin may be achieved using significantly simplified circuit components, such as the high-pass filter 87 and the second comparator 89.

In another embodiment (not shown), the signal detection circuit SD8 includes an analog-to-digital converter (ADC), a memory element, and a microcontroller unit (MCU). The ADC is connected to the differential capacitor 831 to convert the differentiated signal V4 into a digital signal (DS), and the digital signal (DS) is then transmitted to the memory element for storage. The MCU retrieves the stored digital signal (DS) and performs calculations and analysis on the digital signal (DS) to determine whether the differentiated signal V4 exhibits a sudden voltage change, and determine the time point at which the differentiated signal V4 exhibits sudden voltage change.

The implementations of the transimpedance amplifying circuit 82, the differentiation circuit 83, the demodulator 84, the phase-locked loop circuit 85, the high-pass filter 87, and the first comparator 88 in the voltage sensing device 8 having MEMS element may be the same as those of the transimpedance amplifying circuit 62, the differentiation circuit 63, the demodulator 64, the phase-locked loop circuit 65, the high-pass filter 67, and the first comparator 66 shown in FIG. 6, respectively. Similarly, the implementation of the low-pass filter 86 in the voltage sensing device 8 having MEMS element may be to the same as the low-pass filter 56 shown in FIG. 5. The details of these implementations are not repeated herein.

The first input end 891 of the second comparator 89 is configured to receive the filtered voltage V5, while the second input end 892 of the second comparator 89 is configured to receive a second threshold voltage Vth′. According to the filtered voltage V5, the second comparator 89 may rapidly determine whether a sudden voltage drop has occurred. The output end 893 of the second comparator 89 outputs a second comparison result S2 between the filtered voltage V5 and the second threshold voltage Vth′. When the filtered voltage V5 exceeds the second threshold voltage Vth′, the second comparison result S2 indicates that a sudden voltage drop has occurred. In other words, when the input voltage Vin drops suddenly or rise suddenly within a short time interval, the filtered voltage V5 exceeds the second threshold voltage Vth′. Therefore, without performing complex numerical calculation, the second comparator 89 simply compares the filtered voltage V5 with the second threshold voltage Vth′ to rapidly determine whether the input voltage Vin exhibits the sudden voltage drop. In some embodiments, the second threshold voltage Vth′ may be adjusted according to the specific requirements or standards for detecting sudden voltage change.

In some embodiments, both the first comparison result S1 and the second comparison result S2 may be used to drive the silicon controlled rectifier. For instance, when the second comparison result S2 indicates that a sudden voltage drop has occurred, and the first comparison result S1 indicates that the modulated voltage Vout exceeds the first threshold voltage (Vth), it signifies that the input voltage Vin exhibits a sudden voltage change and the amount of change of the input voltage Vin can cause failure or damage to electronic devices or the power system. Under such conditions, the voltage sensing device 8 having the MEMS element may generate a driving signal to drive the silicon controlled rectifier, thereby preventing power outages or conductor breakage in the power system.

Further, the MEMS sensing element 81 includes a driving part 811, a sensing part 812, a movable part 813, two fixed parts 814 and 815 and two elastic parts 816 and 817. The implementation of MEMS sensing element 81 may be the same as that of the MEMS sensing element 71 described with reference to FIG. 7, details are not repeated herein.

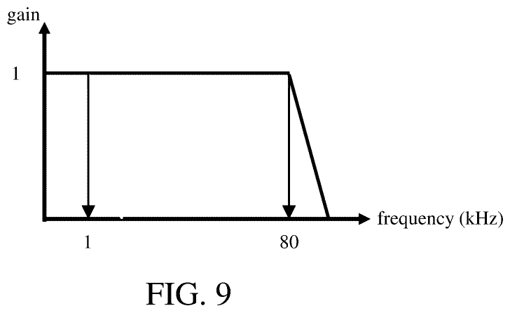

Please refer to FIG. 9, which is a diagram illustrating a sensing result of the voltage sensing device having MEMS element of the disclosure sensing a high frequency signal. As shown in FIG. 9, the sensing bandwidth of the voltage sensing device having MEMS element ranges from 1 kHz to 80 kHz, maintaining a consistent gain throughout this frequency range. Therefore, high frequency signal sensed by the voltage sensing device having MEMS element in this disclosure may not be distorted.

Please refer to FIG. 10, FIG. 11a, and FIG. 11b, wherein FIG. 10 is a diagram illustrating a sensing result of the voltage sensing device having MEMS element of the disclosure under normal voltage condition, FIG. 11a illustrates the sensing result of the voltage sensing device having MEMS element of the disclosure under abnormal voltage condition (sudden voltage drop condition), and FIG. 11b is a partially enlarged diagram of FIG. 11a. The curve P0 is used to represent the input voltage Vin and the curve P1 is used to represent the amplified voltage V3. The amplified voltage V3 may be derived from a first derivative of the square of the input voltage (Vin²). The curve P2 is used to represent the filtered voltage V5. The high-pass filter 67 filters the differentiated signal V4 to generate the filtered voltage V5, where the differentiated signal V4 may be derived from a second derivative of the square of the input voltage (Vin²). As shown in FIG. 10, under normal voltage condition, the trend of curve P1 corresponds to the trend of curve P0. Specifically, when the input voltage Vin, represented by curve P0, increases steadily without any sudden voltage drop or sudden voltage rise, the amplified voltage V3, represented by curve P1, correspondingly rises steadily and then decreases steadily. During this period, the filtered voltage V5, represented by curve P2, remains near zero in FIG. 10.

In FIG. 11a and FIG. 11b, when the input voltage Vin on curve P0 exhibits a sudden voltage change (e.g., sudden voltage drop at data point P01 in FIG. 11b), the amplified voltage V3 on curve P1 drops suddenly, and a pulse rise significantly in the filtered voltage V5 on curve P2. For example, in FIG. 11a and FIG. 11b, when the input voltage Vin represented by curve P0 drops suddenly at 0.0005 seconds, the amplified voltage V3 on curve P1 correspondingly exhibits a sudden voltage drop, while the filtered voltage V5 on curve P2 exhibits a sudden voltage rise. When the magnitude of the sudden voltage drop in the amplified voltage V3 represented by curve P1 exceeds a predetermined value, it indicates that the input voltage Vin exhibits a sudden voltage change. The time point at which the magnitude of sudden voltage drop of the curve P1 exceeds the threshold is the time point at which the sudden voltage change occurs in the input voltage Vin—for example, at 0.0005 seconds in FIG. 11a and FIG. 11b. Furthermore, when the filtered voltage V5 represented by curve P2 exceeds the second threshold voltage Vth′, it signifies that the input voltage Vin has exhibited a sudden voltage change. The time point at which the filtered voltage V5 exceeds the second threshold voltage Vth′ marks the occurrence of the sudden voltage change of the input voltage Vin, such as the 0.0005-second time point shown in FIG. 11a and FIG. 11b.

Please refer to FIG. 11c to FIG. 11f, wherein FIG. 11c is an example of an input voltage input to the MEMS sensing element. In FIG. 11c, the input voltage is illustrated as a sine wave function, and the input voltage Vin may be expressed by V₀·sin(2φωt). FIG. 11d illustrates a square of the input voltage of FIG. 11c and the waveform of a square of the sine wave function (the waveform of [V₀·sin(2πωt)]²) is shown in FIG. 11d. FIG. 11e illustrates the first derivative derived from differentiating the square of the input voltage shown in FIG. 11d. FIG. 11f illustrates the second derivative derived from further differentiating the first derivative shown in FIG. 11e. As shown in FIG. 11c, when the AC voltage exhibits a sudden voltage drop at the first time point t1, the square of the input voltage function in FIG. 11d also exhibits a sudden voltage drop at the first time point t1. Additionally, at this first time point t1, the first derivative of the square of the input voltage depicted in FIG. 11e generates a first pulse IPL1, which includes both positive and negative values. Furthermore, the second derivative of the square of the input voltage illustrated in FIG. 11f generates a second pulse IPL2 at time t1, which lies entirely within the positive range.

Please refer to FIG. 11g to FIG. 11j, wherein FIG. 11g is another example of an input voltage Vin input to the MEMS sensing element. In FIG. 11g, the input voltage Vin is illustrated as a sine wave function, and the input voltage Vin may be expressed by V₀·sin(2φωt). FIG. 11h illustrates a square of the voltage, which is a square of the input voltage of FIG. 11g and the waveform of a square of the sine wave function (the waveform of [V₀·sin(2φωt)]²) is shown in FIG. 11h. FIG. 11i illustrates the first derivative of the square of the input voltage shown in FIG. 11h. FIG. 11j illustrates the second derivative of the square of the input voltage shown in FIG. 11i. As shown in FIG. 11g, when the AC voltage exhibits a sudden voltage drop at the second time point t2, the square of the input voltage function in FIG. 11h also exhibits a sudden voltage drop at the same time point t2. Additionally, at this second time point t2, the first derivative of the square of the input voltage depicted in FIG. 11i generates a third pulse IPL3, which includes both positive and negative values. Furthermore, the second derivative of the square of the input voltage shown in FIG. 11j generates a fourth pulse IPL4 at t2, which lies entirely within the positive range. In other words, regardless of whether the pulse of the first derivative of the square of the input voltage falls within positive range or negative range, the second derivative of the square of the input voltage always generates a pulse that lies entirely within the positive range.

Therefore, as illustrated in FIG. 10 and FIGS. 11a through 11j, the voltage sensing device having a MEMS element disclosed herein may accurately determine the voltage value when the voltage drops suddenly or rises suddenly, as well as determine the corresponding time point.

Please refer to FIG. 12, which is a schematic diagram illustrating a voltage sensing device having MEMS element according to an eighth embodiment of the disclosure. As shown in FIG. 12, the voltage sensing device 9 having MEMS element includes a MEMS sensing element 91, a transimpedance amplifying circuit 92, a differentiation circuit 93, a demodulator 94, a phase-locked loop circuit 95, a low-pass filter 96, a first comparator 97, a signal adjustment element 98, a high-pass filter 99 and a second comparator 100. The implementations of the MEMS sensing element 91, the transimpedance amplifying circuit 92, the demodulator 94, the phase-locked loop circuit 95, the low-pass filter 96, the first comparator 97, the high-pass filter 99, and the second comparator 100 shown in FIG. 12 may be the same as those of the MEMS sensing element 81, the transimpedance amplifying circuit 82, the demodulator 84, the phase-locked loop circuit 85, the low-pass filter 86, the first comparator 88, the high-pass filter 87, and the second comparator 89 illustrated in FIG. 8. The details of these implementations are not repeated herein.

Compared to the voltage sensing device 8 having a MEMS element shown in FIG. 8, the differentiation circuit 93 in FIG. 12 includes a differential capacitor 931 and a differential resistor 932. One end of the differential capacitor 931 is connected to the output end of the transimpedance amplifying circuit 92, while another end of the differential capacitor 931 connects to one end of the differential resistor 932, where another end of the differential resistor 932 is grounded. Furthermore, the voltage sensing device 9 having a MEMS element may also include a signal adjustment element 98. The first input end of the signal adjustment element 98 is connected to the output end of the differentiation circuit 93, the second input end of signal adjustment element 98 is connected to the output end of the phase-locked loop circuit 95, and an output end of the signal adjustment element 98 is connected to the input end of the high-pass filter 99.

After the input voltage Vin is applied to the MEMS sensing element 91, the MEMS sensing element 91 generates the sensed current I1. The transimpedance amplifying circuit 92 converts this sensed current I1 into the amplified voltage V3, which may be derived from amplifying the first derivative of the square of the voltage difference. The transimpedance amplifying circuit 92 then outputs the amplified voltage V3 to the differentiation circuit 93, and the differentiation circuit 93 performs another differentiation on the amplified voltage V3 to generate a first voltage V_{A} (differentiated signal). In other words, the first voltage V_{A} is a signal which may be derived from a second derivative of the square of the voltage difference and amplified. The differentiation circuit 93 outputs the first voltage V_{A} to the first input end of the signal adjustment element 98.

The second voltage V_{B}, generated by the phase-locked loop circuit 95 through frequency locking, is output to both the demodulator 94 and the first input end of the signal adjustment element 98. The signal adjustment element 98 includes a subtractor (not shown in FIG. 12) that compares the first voltage V_{A} and the second voltage V_{B}, and lowers the voltage level of V_{A} into a range that can be processable by the high-pass filter 99 and the second comparator 100 according to the comparison result. The signal adjustment element 98 then outputs the lowered first voltage to the high-pass filter 99, wherein the lowered first voltage falls within a range that can be processed by the high-pass filter. The operations of the high-pass filter 99 and the second comparator 100 may be the same as that of the high-pass filter 87 and second comparator 89 shown in FIG. 8, respectively; their details are not repeated here.

Taking FIG. 12 as an example, the input voltage Vin, the sensed current I1, the amplified voltage V3, and the first voltage V_{A} may be expressed by equations (1) through (4) below, where Vₒ represents the peak (maximum) voltage of the AC signal, Q is the total electric charge, and ω is the frequency of the AC signal. In other words, the amplified voltage V3 in equation (3) corresponds to the voltage which is derived from amplifying the first derivative of the square of the input voltage Vin (or voltage difference). The first voltage V_{A} in equation (4) is obtained by differentiating the amplified voltage V3 once.

$$Vin = {V}_{0} \times sin ( 2 πω t ) \qquad equation ( 1 )$$

$$I 1 = \frac{dQ}{dt} \qquad equation ( 2 )$$

$$V 3 = {[ {V}_{0} \times {sin}^{2} ( 2 πω t ) ]}^{′} \qquad equation ( 3 )$$

$${V}_{A} = {[ {V}_{0} \times {sin}^{2} ( 2 πω t ) ]}^{″} \qquad equation ( 4 )$$

Additionally, taking FIGS. 11c through 11j as examples, the waveforms in FIGS. 11c and 11g correspond to equation (1), the waveforms in FIGS. 11d and 11h correspond to the square of the sine wave function in equation (1), the waveforms in FIGS. 11e and 11i correspond to equation (3), and the waveforms in FIGS. 11f and 11j correspond to equation (4).

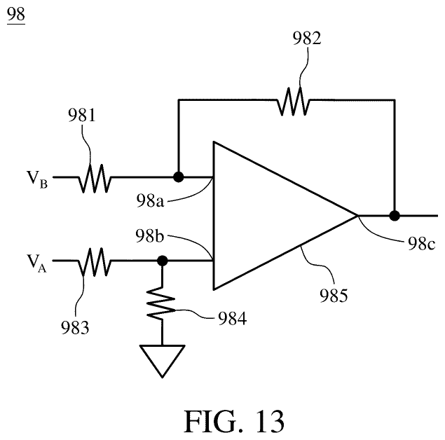

Please refer to FIG. 13, which is a circuit diagram illustrating an implementation of a signal adjustment element. The signal adjustment element 98 shown in FIG. 13 may be implemented by a subtractor and is applicable to the signal adjustment element 98 depicted in FIG. 12. As illustrated in FIG. 13, the signal adjustment element 98 comprises a first resistor 981, a second resistor 982, a third resistor 983, a fourth resistor 984, and a comparator 985. The comparator 985 includes two input ends, 98a and 98b, and one output end, 98c.

In FIG. 13, one end of the first resistor 981 is connected to the output end of the phase-locked loop circuit 95 in FIG. 12 to receive the second voltage V_{B}. Another end of the first resistor 981 is connected to input end 98a of the comparator 985 and one end of the second resistor 982. Another end of the second resistor 982 is connected to the output end 98c of the comparator 985. The output end 98c of the comparator 985 is further connected to an input end of the high-pass filter 99 in FIG. 12. One end of the third resistor 983 is connected to the output end of the differentiation circuit 93 in FIG. 12 to receive the first voltage V_{A}. Another end of the third resistor 983 is connected to one end of the fourth resistor 984 and the input end 98b of the comparator 985, while another end of the fourth resistor 984 is grounded.

The first resistor 981 and the third resistor 983 may each have a first resistance value, while the second resistor 982 and the fourth resistor 984 may each have a second resistance value. The first resistance value may be higher than the second resistance value. For example, the ratio of the second resistance value to the first resistance value may be approximately 1.25×10⁻⁷; however, this value is provided for exemplarily purposes only and the disclosure is not limited to this ratio.

Therefore, the voltage output by the comparator 985, denoted as V_{c}, may be calculated using equation (5) below, where k represents the ratio of the second resistance value to the first resistance value, V_{A} is the first voltage output from the differentiation circuit 93, and V_{B} is the second voltage output from the phase-locked loop circuit 95.

$${V}_{c} = k \times ( {V}_{A} - {V}_{B} ) \qquad equation ( 5 )$$

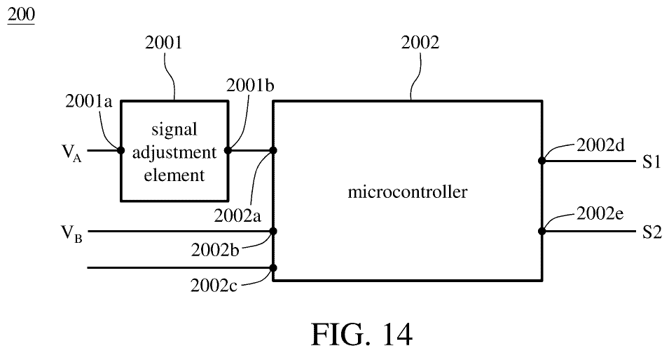

Please refer to FIG. 12 and FIG. 14, wherein FIG. 14 is a partial schematic diagram illustrating a voltage sensing device having MEMS element according to a ninth embodiment of the disclosure. For description convenience, FIG. 14 illustrates an output circuit 200. The output circuit 200 may replace the first comparator 97, the high-pass filter 99 and the second comparator 100 shown in FIG. 12, by digitally performing the functions of the first comparator 97, the high-pass filter 99 and the second comparator 100. The output circuit 200 includes a signal adjustment element 2001 and a microcontroller 2002. The signal adjustment element 2001 may be the signal adjustment element 98 of FIG. 12. The microcontroller 2002 replaces the first comparator 97, the high-pass filter 99, and the second comparator 100 from FIG. 12. Specifically, the microcontroller 2002 digitally performs the function of the first comparator 97 comparing the modulated voltage Vout and the first threshold voltage Vth to generate the first comparison result S1, the function of the high-pass filter 99 filtering the differentiated signal to generate the filtered voltage and the function of the second comparator 100 comparing the filtered voltage V5 and the second threshold voltage Vth′ to generate the second comparison result S2.

The input end 2001a of the signal adjustment element 2001 is connected to the output end of the differentiation circuit 93 to receive the first voltage V_{A}. The output end 2001b of the signal adjustment element 2001 is connected to the first input end 2002a of the microcontroller 2002, while the second input end 2002b of the microcontroller 2002 is connected to the output end of the phase-locked loop circuit 95 to receive the second voltage V_{B}. Additionally, the microcontroller 2002 may further include a third input end 2002c, which is connected to the non-grounded end of the low-pass filter 96.

The signal adjustment element 2001 may include a voltage-dividing resistor configured to lower the first voltage V_{A} into a voltage range that can be processable by the microcontroller 2002. The microcontroller 2002 may receive the adjusted voltage from the signal adjustment element 2001, filter the first voltage V_{A} to generate the filtered voltage V5, compare the first voltage V_{A} with the first threshold voltage Vth to generate a first comparison result S1, which is output through output end 2002d, and compare the filtered voltage V5 with the second threshold voltage Vth′ to generate a second comparison result S2, which is output through output end 2002e.

Please refer to FIG. 12 and FIG. 14. In an embodiment, the microcontroller 2002 shown in FIG. 14 may also be connected to the output end of the differentiation circuit 93 and to the non-grounded end of the low-pass filter 96. As a result, the microcontroller 2002 may replace the first comparator 97, the signal adjustment element 98, the high-pass filter 99, and the second comparator 100 shown in FIG. 12.

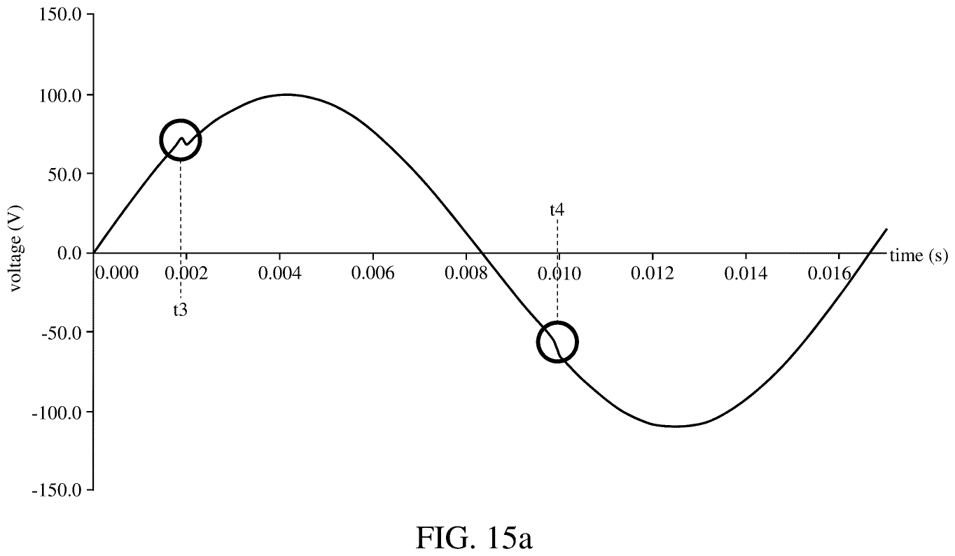

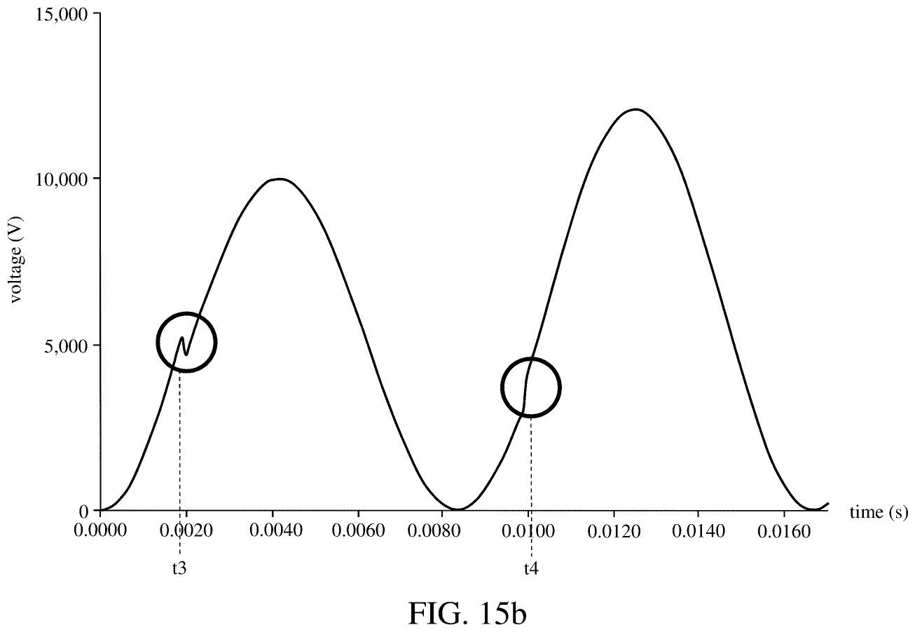

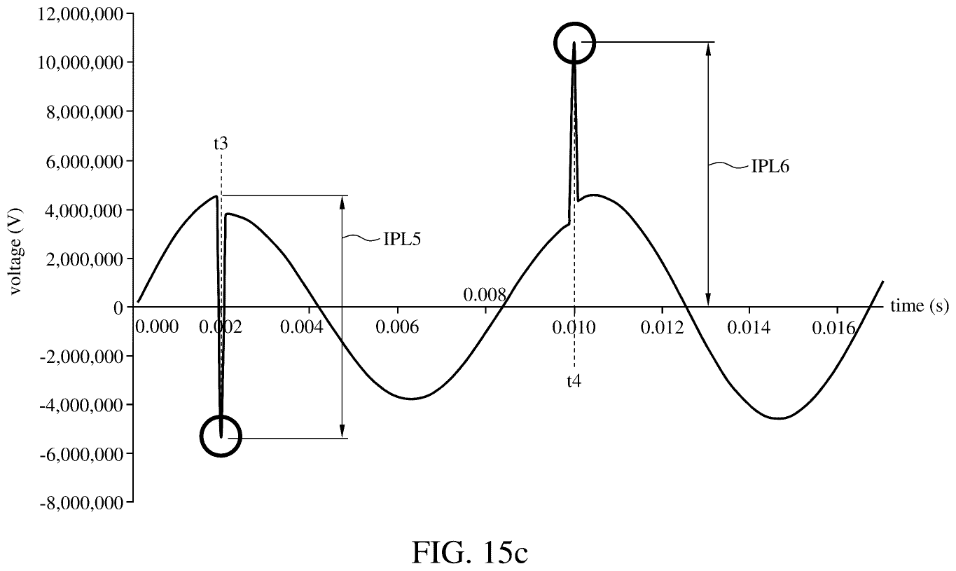

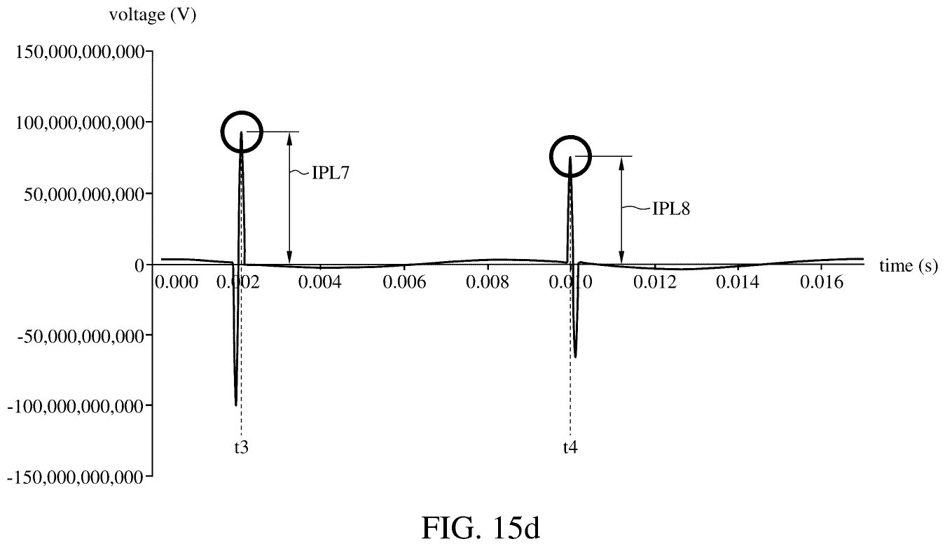

Please refer to FIG. 15a to FIG. 15d. FIG. 15a illustrates an example of an input voltage applied to the MEMS sensing element including a sudden voltage drop and sudden voltage recovery and FIG. 15b shows an example of the square of the input voltage obtained from FIG. 15a. FIG. 15c illustrates the first derivative of the square of the input voltage in FIG. 15b, and FIG. 15d shows the second derivative of the square of the input voltage in FIG. 15b. As illustrated in FIG. 15a, the input voltage (AC voltage) undergoes two events: a sudden voltage drop at the third time point t3 and a sudden voltage recovery at the fourth time point t4. These events cause the square of the input voltage, shown in FIG. 15b, to exhibit a sudden voltage drop at the third time point t3 and a sudden voltage recovery at the fourth time point t4, respectively. Correspondingly, the first derivative of the square of the input voltage in FIG. 15c generates a fifth pulse IPL5, which includes both positive and negative values at the third time point t3, and a sixth pulse IPL6, includes positive values, at the fourth time point t4. Additionally, the second derivative of the square of the input voltage shown in FIG. 15d generates a positive seventh pulse IPL7 which lies entirely within the positive range at the third time point t3 and a positive eighth pulse IPL8 which lies entirely within the positive range at the fourth time point t4.

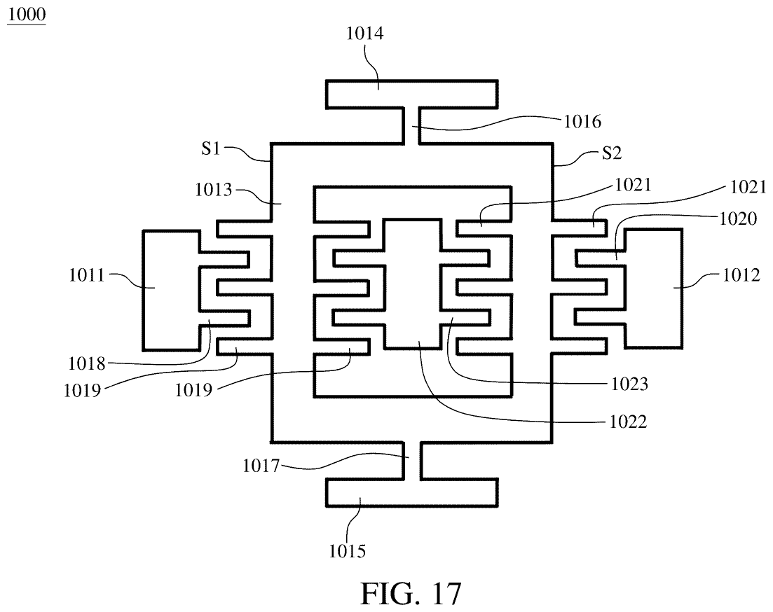

Please refer to FIG. 16, which is a schematic diagram illustrating a voltage sensing device having MEMS element according to a tenth embodiment of the disclosure. The voltage sensing device 9′ having MEMS element shown in FIG. 17 is similar to the voltage sensing device 9 having MEMS element shown in FIG. 12, the same features will not be repeated here. The voltage sensing device 9′ having MEMS element of FIG. 16 further includes a full wave rectifier 90. The full wave rectifier (e.g., full-bridge full wave rectifier) 90 includes a first diode D₁, a second diode D₂, a third diode D₃ and a fourth diode D₄. A cathode of the first diode D₁ is connected to a cathode of the third diode D₃. An anode of the first diode D₁ is connected to a cathode of the fourth diode D₄. An anode of the second diode D₂ is connected to an anode of the fourth diode D₄. A cathode of second diode D₂ is connected to an anode of the third diode D₃. Further, a node between the cathode of the first diode D₁ and the cathode of the third diode D₃ is connected to the driving part 911 of the MEMS sensing element 91. A node between the anode of the fourth diode D₄ and the anode of the second diode D₂ is grounded. In FIG. 16, the full wave rectifier 90 (e.g., full-bridge full wave rectifier) may convert the AC voltage Vac into the input voltage Vin. The AC voltage Vac may be expressed as sin(t), and the input voltage Vin may be expressed as |sin(t)|. Therefore, the frequency of the input voltage Vin is twice that of the AC voltage Vac, and the values of the input voltage Vin are all positive. The input voltage Vin may be input to the driving part 911, and the body voltage Vbody of the movable part 913 may be set to a negative value. Accordingly, the voltage difference between the driving part 911 and the movable part 913 may be a sum of an absolute value of the input voltage (Vin) and an absolute value of the body voltage (Vbody), expressed as |sin(t)|+|Vbody|. The displacement of the movable part 913 may be proportional to the amplified square of the voltage difference between the driving part 911 and the movable part 913. That is, the amount of displacement of the movable part 913 may be proportional to (|sin(t)|+|Vbody|)². The quantity of electric charge accumulated in the movable part 913 may be proportional to the amplified square of the voltage difference between the driving part 911 and the movable part 913. That is, the quantity of electric charge of the movable part 913 may be proportional to (|sin(t)|+|Vbody|)². Accordingly, the sensing sensitivity of the voltage sensing device 9′ having MEMS element may be improved when a voltage is sensed.

Please refer to FIG. 17, wherein FIG. 17 is a structural diagram illustrating the MEMS sensing element according to another embodiment of the disclosure. As shown in FIG. 17, the MEMS sensing element 1000 includes a driving part 1011, a sensing part 1012, a movable part 1013, fixed parts 1014 and 1015, elastic parts 1016 and 1017, a fixed input electrode 1018, a movable electrode 1019, a fixed output electrode 1020, a movable electrode 1021, a central fixed part 1022 and a central fixed electrode 1023.

The movable part 1013 is a ring-shaped movable part and disposed between the driving part 1011 and the sensing part 1012. The movable part 1013 includes an outer side S1 adjacent to the driving part 1011. The movable electrode 1019 at the outer side S1 and the fixed input electrode 1018 on the driving part 1011 form a driving capacitor. The movable part 1013 includes another outer side S2 adjacent to the sensing part 1012. The movable electrode 1021 at another outer side S2 and the fixed output electrode 1020 of the sensing part 1012 form a sensing capacitor. The driving part 1011 includes at least one fixed input electrode 1018, and the sensing part 1012 includes at least one fixed output electrode 1020. The elastic parts 1016 and 1017 are disposed at two sides of the movable part 1013 respectively, the elastic part 1016 is configured to connect the fixed part 1014 to the movable part 1013, and the elastic part 1017 is configured to connect the fixed part 1015 to the movable part 1013. The movable electrode 1019 of the movable part 1013 at the outer side S1 and the fixed input electrode 1018 of the driving part 1011 are arranged in an interdigitated configuration to form an interdigitated electrode, thereby forming a driving capacitor between the movable part 1013 and the driving part 1011. Similarly, the movable electrode 1021 at another outer side S2 and the fixed output electrode 1020 of the sensing part 1012 are arranged in an interdigitated configuration to form another interdigitated electrode, thereby forming a sensing capacitor between the movable part 1013 and the sensing part 1012.

The central fixed part 1022 is disposed at a center of the movable part 1013 (e.g., ring-shaped movable part 1013). Further, the movable electrode 1019, disposed between the driving part 1011 and the central fixed part 1022 and facing the central fixed part 1022, is arranged in an interdigitated configuration with the central fixed electrode 1023 to form an interdigitated electrode. The movable electrode 1021, disposed between the sensing part 1012 and the central fixed part 1022 and facing the central fixed part 1022, is arranged in an interdigitated configuration with the central fixed electrode 1023 to form an interdigitated electrode.

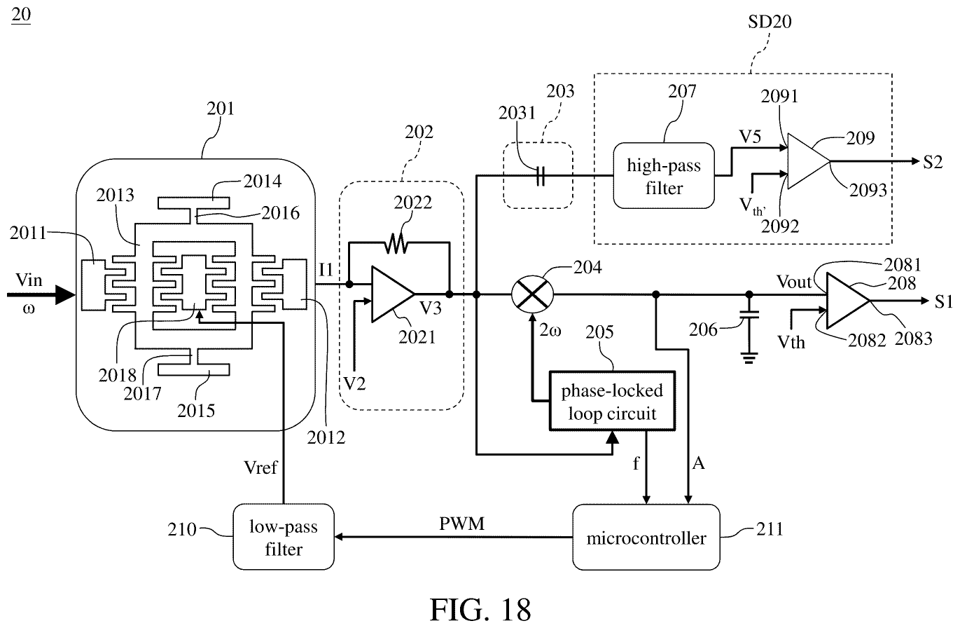

Please refer to FIG. 18, which is a schematic diagram illustrating a voltage sensing device having MEMS element according to an eleventh embodiment of the disclosure. The voltage sensing device 20 having MEMS element shown in FIG. 18 includes a MEMS sensing element 201, a transimpedance amplifying circuit 202, a differentiation circuit 203, a demodulator 204, a phase-locked loop circuit 205, a first low-pass filter 206, a first comparator 208, a second low-pass filter 210, a microcontroller 211 and a signal detection circuit SD20. The transimpedance amplifying circuit 202 is connected to an output end of the MEMS sensing element 201. The differentiation circuit 203 and the demodulator 204 are connected to an output end of the transimpedance amplifying circuit 202, respectively. Further, the differentiation circuit 203 may include a differential capacitor 2031, and one end of the differential capacitor 2031 is connected to the output end of the transimpedance amplifying circuit 202, and another end of the differential capacitor 2031 is connected to an input end of the signal detection circuit SD20. An input end of the phase-locked loop circuit 205 is connected to the output end of the transimpedance amplifying circuit 202, and an output end of the phase-locked loop circuit 205 is connected to an input end of the demodulator 204.

The first comparator 208 includes a first input end 2081, a second input end 2082 and an output end 2083. The input end of the first low-pass filter 206 is connected to an output end of the demodulator 204, and an output end of the first low-pass filter 206 is connected to the first input end 2081 of the first comparator 208. The output end 2083 of the first comparator 208 may be connected to an input end of the silicon controlled rectifier. In the embodiment of FIG. 18, the signal detection circuit SD20 includes a high-pass filter 207 and a second comparator 209. The second comparator 209 includes a first input end 2091, a second input end 2092 and an output end 2093. An input end of the high-pass filter 207 is connected to an output end of the differential capacitor 2031, and an output end of the high-pass filter 207 is connected to the first input end 2091 of the second comparator 209. The implementation of the transimpedance amplifying circuit 202, the differentiation circuit 203, the demodulator 204, the phase-locked loop circuit 205, the first low-pass filter 206, the first comparator 208 and the signal detection circuit SD20 may be to the same as the transimpedance amplifying circuit 82, the differentiation circuit 83, the demodulator 84, the phase-locked loop circuit 85, the low-pass filter 86, the first comparator 88, and the signal detection circuit SD8 shown in FIG. 8. Therefore, detailed descriptions of these components are omitted for brevity.

The MEMS sensing element 201 includes a driving part 2011, a sensing part 2012, a movable part 2013, fixed parts 2014 and 2015, elastic parts 2016 and 2017 and a central fixed electrode 2018. The implementation of the MEMS sensing element 201 may be the same as the MEMS sensing element 1000 described with reference to FIG. 17, details thereof are not repeated herein.

In the embodiment of FIG. 18, the microcontroller 211 may be connected to the second low-pass filter 210 to output a pulse width modulation signal (PWM) to the second low-pass filter 210. Further, the microcontroller 211 may be connected to the output end of the phase-locked loop circuit 205 to receive a frequency f output by the phase-locked loop circuit 205. The microcontroller 211 may be further connected to the output end of the demodulator 204 to receive an amplitude A of the signal output by the output end of the demodulator 204. The second low-pass filter 210 outputs a reference voltage V_{ref} to the central fixed electrode 2018. When the input voltage Vin does not exhibit the sudden voltage change, the voltage difference between the input voltage Vin and the reference voltage V_{ref} is zero, resulting in no displacement of the movable part 2013. Therefore, the amplified voltage V3 remains at zero. On the contrary, when a sudden voltage change occurs in the input voltage Vin, the voltage difference between the input voltage Vin and the reference voltage V_{ref} becomes nonzero. At this time point, the voltage difference between the input voltage Vin and the reference voltage V_{ref} which is obtained by subtracting the reference voltage V_{ref} from the input voltage Vin is greater than zero. As a result, the movable part 2013 is displaced. At this time, the sensed current I1 decreases, which leads to a corresponding decrease in the amplified voltage V3. Therefore, the voltage value output by the differentiation circuit 203 may have a lower value, and therefore, the subtractor (for example, the subtractor in FIG. 13) may be omitted.

In view of the above, the voltage sensing device having MEMS element according to one or more embodiments of the disclosure accurately determine the magnitude and corresponding time points of sudden voltage drop or sudden voltage rise within an extremely short time interval (e.g., within 1 millisecond). Moreover, the voltage sensing device having MEMS element according to one or more embodiments of the disclosure may increase the sensing bandwidth, for example, up to 80 kHz, based on the stiffness of the elastic portion and/or the mass of the movable part. According to one or more embodiments of the disclosure, no direct current flows through the MEMS sensing element during sensing operation, thereby minimizing energy loss during voltage measurement. Additionally, the large dimensions of the first gap and the second gap of the voltage sensing device having MEMS element according to one or more embodiments of the disclosure may effectively ensure the applicability of the voltage sensing device for measuring high voltages.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. A voltage sensing device having micro electro mechanical system (MEMS) element, comprising:
a MEMS sensing element configured to sense an input voltage to generate a sensed current;
a transimpedance amplifying circuit connected to an output end of the MEMS sensing element to receive the sensed current and convert the sensed current into an amplified voltage; and
a differentiation circuit connected to an output end of the transimpedance amplifying circuit, and configured to receive the amplified voltage and differentiate the amplified voltage to generate a differentiated signal.

2. The voltage sensing device having MEMS element according to claim 1, further comprising: a signal detection circuit connected to an output end of the differentiation circuit, the signal detection circuit configured to detect the differentiated signal, determine whether the differentiated signal exhibits a sudden voltage change, and identifies a time point of the sudden voltage change.

3. The voltage sensing device having MEMS element according to claim 1, further comprising a demodulator connected to the output end of the transimpedance amplifying circuit and configured to modulate the amplified voltage to generate a modulated voltage.

4. The voltage sensing device having MEMS element according to claim 3, further comprising a phase-locked loop circuit, wherein an input end of the phase-locked loop circuit is connected to the output end of the transimpedance amplifying circuit, and an output end of the phase-locked loop circuit is connected to the demodulator.

5. The voltage sensing device having MEMS element according to claim 4, further comprising a first comparator, and the first comparator comprising:
a first input end connected to an output end of the demodulator to receive the modulated voltage;
a second input end configured to receive a first threshold voltage; and
an output end configured to output a first comparison result between the modulated voltage and the first threshold voltage.

6. The voltage sensing device having MEMS element according to claim 2, further comprising a demodulator connected to the output end of the transimpedance amplifying circuit and configured to modulate the amplified voltage to generate a modulated voltage, wherein the signal detection circuit determines the differentiated signal exhibiting the sudden voltage change when the modulated voltage at the time point exceeds a first threshold voltage and a voltage drop of the modulated voltage within a time interval comprising the time point exceeds a default magnitude.

7. The voltage sensing device having MEMS element according to claim 5, further comprising a low-pass filter connected between the output end of the demodulator and the first input end of the comparator, the low-pass filter configured to filter the modulated voltage.

8. The voltage sensing device having MEMS element according to claim 7, further comprising:
a signal adjustment element connected to the differentiation circuit and the phase-locked loop circuit;
a high-pass filter connected to an output end of the signal adjustment element; and
a second comparator connected to output end of the high-pass filter,
wherein the signal adjustment element is configured to use a comparison result between the differentiated signal and a voltage output by the phase-locked loop circuit to lower a voltage level of the differentiated signal into a voltage range that is processable by the high-pass filter and the second comparator.

9. The voltage sensing device having MEMS element according to claim 8, wherein the signal adjustment element comprises a subtractor, the subtractor comprises a first input end, a second input end and an output end, the first input end of the subtractor is connected to the differentiation circuit, the second input end of the subtractor is connected to the output end of the phase-locked loop circuit, and the output end of the subtractor is connected to an input end of the high-pass filter, and wherein the subtractor is configured to use the comparison result between the differentiated signal and the voltage output by the phase-locked loop circuit to lower a voltage level of the differentiated signal into the voltage range that is processable by the high-pass filter and the second comparator.

10. The voltage sensing device having MEMS element according to claim 5, further comprising a silicon controlled rectifier connected to the output end of the first comparator, the silicon controlled rectifier configured to be driven when the first comparison result indicates that the modulated voltage exceeds the first threshold voltage.

11. The voltage sensing device having MEMS element according to claim 1, wherein the differentiation circuit comprises a differential capacitor.

12. The voltage sensing device having MEMS element according to claim 1, wherein the differentiated signal is a voltage which is derived from a second derivative of a square of the input voltage.

13. The voltage sensing device having MEMS element according to claim 2, wherein the signal detection circuit determines the differentiated signal exhibiting the sudden voltage change when an amount of change of the differentiated signal exceeds a default threshold within a time interval, wherein a middle point of the time interval is the time point of the sudden voltage change in differentiated signal.

14. The voltage sensing device having MEMS element according to claim 2, wherein the signal detection circuit further comprises a high-pass filter, and the high-pass filter is connected to the output end of the differentiation circuit and configured to filter the differentiated signal to generate a filtered voltage.

15. The voltage sensing device having MEMS element according to claim 4, further comprising an output circuit, and the output circuit comprising:
a signal adjustment element having an input end and an output end, wherein the input end of the signal adjustment element is connected to the output end of the differentiation circuit to receive the differentiated signal; and
a microcontroller having two input ends and two output ends, the two input ends of the microcontroller connected to the output end of the signal adjustment element and the output end of the phase-locked loop circuit respectively, and the microcontroller configured to filter the differentiated signal to generate a filtered voltage,
wherein the signal adjustment element is configured to lower a voltage level of the differentiated signal into a voltage range that is processable by the microcontroller, and
wherein one of the two output ends of the microcontroller is configured to output a first comparison result between the modulated voltage and a first threshold voltage, and another one of the two output ends of the microcontroller is configured to output a second comparison result between the filtered voltage and a second threshold voltage.

16. The voltage sensing device having MEMS element according to claim 14, wherein the filtered voltage generates a pulse at the time point of the sudden voltage change when the differentiated signal exhibits the sudden voltage change, and the pulse lies entirely within the positive range.

17. The voltage sensing device having MEMS element according to claim 15, wherein the second comparison result indicates a sudden voltage change in the differentiated signal when the filtered voltage exceeds the second threshold voltage.

18. The voltage sensing device having MEMS element according to claim 14, further comprising a second comparator, and the second comparator comprising:
a first input end connected to an output end of the high-pass filter to receive the filtered voltage;
a second input end configured to receive a second threshold voltage; and
an output end configured to output a second comparison result between the filtered voltage and the second threshold voltage.

19. The voltage sensing device having MEMS element according to claim 1, wherein the MEMS sensing element comprises:
a driving part;
a sensing part;
a movable part disposed between the driving part and the sensing part, wherein one side of the movable part and the driving part form a first capacitor, and another side of the movable part and the sensing part form a second capacitor;
two fixed parts; and
two elastic parts disposed at two sides of the movable part, respectively, wherein one of the two elastic parts is configured to connect one of the two fixed parts to the movable part, and another one of the two elastic parts is configured to connect another one of the two fixed parts to the movable part.

20. The voltage sensing device having MEMS element according to claim 19, wherein a sensing bandwidth of the MEMS sensing element is expanded by adjusting a stiffness of the two elastic parts and a mass of the movable part, and wherein the sensing bandwidth is proportional to a square root of the stiffness of the two elastic parts, and inversely proportional to a square root of the mass of the movable part.

21. The voltage sensing device having MEMS element according to claim 19, wherein the driving part comprises at least one fixed input electrode, the sensing part comprises at least one fixed output electrode, two sides of the movable part comprise two movable electrodes respectively, the at least one fixed input electrode and one of the two movable electrodes have an input gap therebetween, the at least one fixed output electrode and another one of the two movable electrodes have an output gap therebetween, and a maximum input voltage of the MEMS sensing element is proportional to a dimension of the input gap and a dimension of the output gap.

22. The voltage sensing device having MEMS element according to claim 21, wherein the driving part and the sensing part maintain a constant distance therebetween, and each of the dimension of the input gap and the dimension of the output gap is proportional to a square of the maximum input voltage of the MEMS sensing element.

23. The voltage sensing device having MEMS element according to claim 8, further comprising:
a second low-pass filter connected to the MEMS sensing element and configured to output a reference voltage to the MEMS sensing element; and
a microcontroller connected to the second low-pass filter, the output end of the phase-locked loop circuit and the output end of the demodulator, wherein the microcontroller is configured to receive a frequency and an amplitude of a signal output by the phase-locked loop circuit and output a pulse width modulation signal to the second low-pass filter.

24. The voltage sensing device having MEMS element according to claim 23, wherein the MEMS sensing element comprises:
a driving part;
a sensing part;
a movable part being a ring-shaped movable part and disposed between the driving part and the sensing part, wherein one side of the movable part and the driving part form a driving capacitor, and another side of the movable part and the sensing part form a sensing capacitor;
a central fixed part disposed at a center of the movable part;
two fixed parts; and
two elastic parts disposed at two sides of the movable part respectively, one of the two elastic parts configured to connect one of the two fixed parts to the movable part, and another one of the two elastic parts configured to connect another one of the two fixed parts to the movable part,
wherein the second low-pass filter outputs the reference voltage to the central fixed part, and a difference value of the input voltage subtracted by the reference voltage is greater than zero when the input voltage exhibits the sudden voltage change to displace the movable part.

25. A voltage sensing device having MEMS element, comprising:
a MEMS sensing element, comprising:
at least one fixed part;
a movable part;
at least one elastic part connected to the at least one fixed part and the movable part;
a sensing part; and
a driving part configured to sense an input voltage;
wherein the input voltage induces a voltage difference between the driving part and the movable part, and the voltage difference displaces the movable part to induce a sensed current in the sensing part, and a displacement of the movable part is proportional to a square of the voltage difference;
a transimpedance amplifying circuit connected to an output end of the MEMS sensing element to receive the sensed current and convert the sensed current into an amplified voltage, wherein the amplified voltage is derived from a first derivative of a square of the voltage difference and amplifying the first derivative of the square of the voltage difference;
a differentiation circuit connected to an output end of the transimpedance amplifying circuit, and configured to receive the amplified voltage and differentiate the amplified voltage to generate a differentiated signal; and
a signal detection circuit connected to an output end of the differentiation circuit, and configured to detect the differentiated signal, determine whether the differentiated signal exhibits a sudden voltage change, and identifies a time point of the sudden voltage change in the differentiated signal.

26. The voltage sensing device having MEMS element according to claim 25, wherein the input voltage is applied to the MEMS sensing element to cause a vibration frequency of the movable part to be twice a frequency of an alternating voltage.

27. The voltage sensing device having MEMS element according to claim 26, wherein the input voltage is the alternating voltage, and a body voltage of the movable part is zero to cause the voltage difference to equal the input voltage.

28. The voltage sensing device having MEMS element according to claim 26, wherein the MEMS sensing element further comprises a full wave rectifier, the alternating voltage is input to the full wave rectifier to generate the input voltage, a body voltage of the movable part is less than zero to cause the voltage difference to be a sum of an absolute value of the input voltage and an absolute value of the body voltage.

29. The voltage sensing device having MEMS element according to claim 25, wherein the sensing part generates a plurality of electric charges, and a quantity of the plurality of electric charges is proportional to a square of the voltage difference.

30. The voltage sensing device having MEMS element according to claim 25, wherein the input voltage is configured to cause a frequency of the sensing current to be twice a frequency of an alternating voltage.

31. The voltage sensing device having MEMS element according to claim 30, wherein the input voltage is the alternating voltage, and a body voltage of the movable part is zero.

32. The voltage sensing device having MEMS element according to claim 30, wherein the MEMS sensing element further comprises a full wave rectifier, the alternating voltage is input to the full wave rectifier to generate the input voltage, and a body voltage of the movable part is less than zero.
